(19) United States
(12) Patent Application Publication
(10) Pub. No.: US 2025/0221274 A1
(43) Pub. Date: Jul. 3, 2025

(54) DISPLAY PANEL AND DISPLAY APPARATUS

(71) Applicant: LG Display Co., Ltd., Seoul (KR)

(72) Inventors: Inae CHOI, Paju-si (KR); Hyemin PARK, Paju-si (KR); Sejong SEONG, Paju-si (KR)

(73) Assignee: LG Display Co., Ltd., Seoul (KR)

(21) Appl. No.: 18/924,761

(22) Filed: Oct. 23, 2024

(30) Foreign Application Priority Data
Dec. 28, 2023 (KR) 10-2023-0194666

(51) Int. Cl. H10K 59/80; H10K 59/131; H10K 59/35

(52) U.S. Cl. CPC H10K 59/878; H10K 59/131; H10K 59/352; H10K 59/879

(57) ABSTRACT

A display panel can include a first subpixel and a second subpixel disposed on a substrate, the first subpixel being adjacent to the second subpixel, the first subpixel having a first light emission area and the second subpixel having a second light emission area. The display panel further includes a pixel electrode disposed in the first subpixel, and an insulation layer disposed between the pixel electrode and the substrate. The insulation layer includes a plurality of concave portions including a first concave portion and a second concave portion having a different shape than the first concave portion. Also, the display panel can further include a pattern portion disposed between the first subpixel and the second subpixel, and a reflective portion overlapping with the pattern portion.

### CROSS-REFERENCE TO RELATED APPLICATIONS

This application claims priority to Korean Patent Application No. 10-2023-0194666 filed on Dec. 28, 2023, the entirety of which is hereby incorporated by reference as if fully set forth herein.

### BACKGROUND

### Field of the Invention

The present disclosure relates to a display panel and a display apparatus for displaying images, which has an improved light extraction efficiency and an improved viewing angle.

### Discussion of the Related Art

Since an organic light emitting display apparatus has a high response speed and low power consumption and self-emits light without requiring a separate light source unlike a liquid crystal display apparatus, a viewing angle can be provided and thus the organic light emitting display apparatus has received attention as a next-generation flat panel display apparatus.

Such a display apparatus displays an image through light emission of a light emitting element layer that includes a light emitting layer interposed between two electrodes.

Also, there is an issue that light extraction efficiency of the display apparatus can be reduced as some of light emitted from the light emitting element layer is not emitted to the outside due to total reflection on the interface between the light emitting element layer and an electrode and/or between a substrate and an air layer.

In addition, there is an issue that light mixing can occur between adjacent subpixels.

Thus, a need exists for improving a light extraction efficiency of a display apparatus.

Also, need exists for preventing light mixing from occurring between adjacent subpixels a display apparatus.

Further, a need exists for a more luminous display apparatus that can be made thinner with fewer layers and also reduces a number of manufacturing steps.

### SUMMARY OF THE DISCLOSURE

An aspect of the present disclosure is directed to providing a display apparatus in which the light extraction efficiency of the light emitted from a light emitting element layer can be improved.

An aspect of the present disclosure is directed to provide a display apparatus capable of providing an improved viewing angle.

An aspect of the present disclosure is directed to providing a display apparatus in which light extraction efficiency can be maximized through light extraction from a non-light emission area.

An aspect of the present disclosure is directed to providing a display apparatus in which the overall power consumption can be reduced by increasing the light extraction from a non-light emission area.

Another aspect of the present disclosure is directed to providing a display panel that includes a first subpixel and a second subpixel disposed on a substrate, the first subpixel being adjacent to the second subpixel, the first subpixel having a first light emission area and the second subpixel having a second light emission area, a pixel electrode disposed in the first subpixel, an insulation layer disposed between the pixel electrode and the substrate, the insulation layer including a plurality of concave portions including a first concave portion and a second concave portion having a different shape than the first concave portion, a pattern portion disposed between the first subpixel and the second subpixel, and a reflective portion overlapping with the pattern portion.

An aspect of the present disclosure is directed to providing a display panel, in which the reflective portion is configured to redirect light emitted from the first subpixel that has passed through one of the plurality of concave portions in a direction toward the substrate.

Yet another aspect of the present disclosure is directed to providing a display panel, in which the pattern portion is a trench formed in the insulation layer, and a lowermost surface of the trench is lower than the pixel electrode.

An aspect of the present disclosure is directed to providing a display panel, in which the trench surrounds at least a majority of an outer perimeter of the pixel electrode of the first subpixel in a plan view, and the trench is spaced apart from the pixel electrode.

Another aspect of the present disclosure is directed to providing a display panel, in which a cross section of the trench has a “V” shape or a “U” shape in a non-emission area between the first subpixel and the second subpixel.

An aspect of the present disclosure is directed to providing a display panel, in which the reflective portion is part of a reflective electrode of the first subpixel that extends continuously across the pattern portion.

Yet another aspect of the present disclosure is directed to providing a display panel, in which the first concave portion overlaps with an edge area of the pixel electrode and the second concave portion overlaps with a center area of the pixel electrode.

An aspect of the present disclosure is directed to providing a display panel, in which the first concave portion at the edge area is wider than the second concave portion.

Another aspect of the present disclosure is directed to providing a display panel, in which the second concave portion is wider than the first concave portion at the edge area.

Another aspect of the present disclosure is directed to providing a display panel, in which a first depth of the first concave portion is different than a second depth of the second concave portion.

An aspect of the present disclosure is directed to providing a display panel that includes a bank disposed on an edge of the pixel electrode and overlapping with an inclined surface of the pattern portion.

An aspect of the present disclosure is directed to providing a display panel that includes a light emitting layer disposed in the first subpixel, the light emitting layer directly contacting an inclined surface of the pattern portion.

Another aspect of the present disclosure is directed to providing a display panel, in which the insulating layer includes a first layer having a first refractive index and a second layer having a second refractive index that is higher than the first refractive index, and the second layer is disposed between the pixel electrode and the first layer.

Yet another aspect of the present disclosure is directed to providing a display panel, in which the first concave portion is one of a plurality of first concave portions in the first subpixel, and the second concave portion is one of a plurality of second concave portions in the first subpixel, and a first aspect ratio of the plurality of first concave portions is different than a second aspect ratio of the plurality of second concave portions.

An aspect of the present disclosure is directed to providing a display apparatus that includes a display panel including a plurality of subpixels, a gate driver configured to supply gate signals to gate lines connected to the plurality of subpixels, and a data driver configured to supply data signals to data lines connected to the plurality of subpixels, in which the display panel includes a first subpixel and a second subpixel disposed on a substrate, the first subpixel being adjacent to the second subpixel, the first subpixel having a first light emission area and the second subpixel having a second light emission area, a pixel electrode disposed in the first subpixel, an insulation layer disposed between the pixel electrode and the substrate, the insulation layer including a plurality of concave portions including a first concave portion and a second concave portion having a different shape than the first concave portion, a pattern portion disposed between the first subpixel and the second subpixel, and a reflective portion overlapping with the pattern portion.

Another aspect of the present disclosure is directed to providing a display apparatus that includes a first data line electrically connected to the first subpixel via a connecting portion of the pixel electrode, in which the pattern portion surrounds at least a majority of an outer perimeter of the pixel electrode of the first subpixel in a plan view, the pattern portion is spaced apart from the pixel electrode, the connecting portion of the pixel electrode passes between adjacent parts of the pattern portion without covering the pattern portion in the plan view, and a portion of the first data line crosses the pattern portion without covering the majority of the pattern portion in the plan view.

Another aspect of the present disclosure is directed to providing a display apparatus, in which the reflective portion is configured to redirect light emitted from the first subpixel that has passed through one of the plurality of concave portions in a direction toward the substrate.

Yet another aspect of the present disclosure is directed to providing a display apparatus, in which the pattern portion is a trench formed in the insulation layer, and a lowermost surface of the trench is lower than the pixel electrode.

An aspect of the present disclosure is directed to providing a display apparatus, in which the trench surrounds at least a majority of an outer perimeter of the pixel electrode of the first subpixel in a plan view, and the trench is spaced apart from the pixel electrode.

Another aspect of the present disclosure is directed to providing a display apparatus, in which a cross section of the trench has a “V” shape or a “U” shape in a non-emission area between the first subpixel and the second subpixel.

An aspect of the present disclosure is directed to providing a display apparatus, in which the reflective portion is part of a reflective electrode of the first subpixel that extends continuously across the pattern portion.

Another aspect of the present disclosure is directed to providing a display apparatus, in which the first concave portion overlaps with an edge area of the pixel electrode and the second concave portion overlaps with a center area of the pixel electrode.

Yet another aspect of the present disclosure is directed to providing a display apparatus, in which the first concave portion at the edge area is wider than the second concave portion.

An aspect of the present disclosure is directed to providing a display apparatus, in which the second concave portion is wider than the first concave portion at the edge area.

Another aspect of the present disclosure is directed to providing a display apparatus, in which a first depth of the first concave portion is different than a second depth of the second concave portion.

An aspect of the present disclosure is directed to providing a display apparatus that includes a bank disposed on an edge of the pixel electrode and overlapping with an inclined surface of the pattern portion.

Another aspect of the present disclosure is directed to providing a display apparatus that includes a light emitting layer disposed in the first subpixel, the light emitting layer directly contacting an inclined surface of the pattern portion.

An aspect of the present disclosure is directed to providing a display apparatus, in which the insulating layer includes a first layer having a first refractive index and a second layer having a second refractive index that is higher than the first refractive index, and the second layer is disposed between the pixel electrode and the first layer.

Another aspect of the present disclosure is directed to providing a display apparatus, in which the first concave portion is one of a plurality of first concave portions in the first subpixel, and the second concave portion is one of a plurality of second concave portions in the first subpixel, and a first aspect ratio of the plurality of first concave portions is different than a second aspect ratio of the plurality of second concave portions.

Yet another aspect of the present disclosure is directed to providing a display apparatus that includes a first data line electrically connected to the first subpixel, in which the first data line does not overlap with the pixel electrode.

The problems to be solved by the examples of the present disclosure are not limited to those mentioned above, and other problems not mentioned will be apparent to one of ordinary skill in the art to which the technical spirits of the present disclosure belong from the following description.

The technical benefits of the present disclosure are not limited to the above-mentioned benefits, and other benefits, which are not mentioned above, can be clearly understood by those skilled in the art from the following descriptions.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain principles of the disclosure. In the drawings:

FIG. 1 is a schematic top view of a display apparatus according to one embodiment of the present disclosure.

FIG. 2 is a schematic plan view illustrating one pixel shown in FIG. 1, according to an embodiment of the present disclosure.

FIG. 3 is a schematic cross-sectional view of lines I-I′ shown in FIG. 2, according to an embodiment of the present disclosure.

FIG. 4 is an enlarged view of portion A of FIG. 3, according to an embodiment of the present disclosure.

FIG. 5 is a schematic cross-sectional view illustrating an example variation of a display apparatus according to an embodiment of the present disclosure.

FIG. 6A is a schematic cross-sectional view of a display apparatus according to another embodiment of the present disclosure.

FIG. 6B is an enlarged view of portion B of FIG. 6A, according to an embodiment of the present disclosure.

FIG. 7A is a schematic cross-sectional view illustrating a variant example of a display apparatus according to the second embodiment of the present disclosure.

FIG. 7B is an enlarged view of portion C of FIG. 7A, according to an embodiment of the present disclosure.

FIG. 8A is a schematic cross-sectional view of a display apparatus according to another embodiment of the present disclosure.

FIG. 8B is an enlarged view of the D portion of FIG. 8A, according to an embodiment of the present disclosure.

FIG. 9A is a schematic cross-sectional view illustrating a variant example of a display apparatus according to another embodiment of the present disclosure, according to an embodiment of the present disclosure.

FIG. 9B is an enlarged view of portion F of FIG. 9A, according to an embodiment of the present disclosure.

### DETAILED DESCRIPTION OF THE EMBODIMENTS

Reference will now be made in detail to the embodiments of the present disclosure, examples of which are illustrated in the accompanying drawings. Wherever possible, the same reference numbers will be used throughout the drawings to refer to the same or like parts. Advantages and features of the present disclosure, and implementation methods thereof will be clarified through following embodiments described with reference to the accompanying drawings.

The present disclosure can, however, be embodied in different forms and should not be construed as limited to the embodiments set forth herein. Rather, these embodiments are provided so that this disclosure will be thorough and complete, and will fully convey the scope of the present disclosure to those skilled in the art.

A shape, a size, a ratio, an angle, and a number disclosed in the drawings for describing embodiments of the present disclosure are merely an example, and thus, the present disclosure is not limited to the illustrated details.

Like reference numerals refer to like elements throughout. In the following description, when the detailed description of the relevant known function or configuration is determined to unnecessarily obscure the important point of the present disclosure, the detailed description will be omitted.

In a situation where “comprise,” “have,” and “include” described in the present specification are used, another part can be added unless “only” is used. The terms of a singular form can include plural forms unless referred to the contrary.

In construing an element, the element is construed as including an error range although there is no explicit description. In describing a position relationship, for example, when a position relation between two parts is described as “on,” “over,” “under,” and “next,” one or more other parts can be disposed between the two parts unless “just” or “direct” is used.

In describing a temporal relationship, for example, when the temporal order is described as “after,” “subsequent,” “next,” and “before,” a situation which is not continuous can be included, unless “just” or “direct” is used.

It will be understood that, although the terms “first,” “second,” etc. can be used herein to describe various elements, these elements should not be limited by these terms.

These terms are only used to distinguish one element from another. For example, a first element could be termed a second element, and, similarly, a second element could be termed a first element, without departing from the scope of the present disclosure.

“X-axis direction,” “Y-axis direction” and “Z-axis direction” should not be construed by a geometric relation only of a mutual vertical relation and can have broader directionality within the range that elements of the present disclosure can act functionally.

The term “at least one” should be understood as including any and all combinations of one or more of the associated listed items. For example, the meaning of “at least one of a first item, a second item and a third item” denotes the combination of all items proposed from two or more of the first item, the second item and the third item as well as the first item, the second item or the third item.

Features of various embodiments of the present disclosure can be partially or overall coupled to or combined with each other and can be variously inter-operated with each other and driven technically as those skilled in the art can sufficiently understand. The embodiments of the present disclosure can be carried out independently from each other or can be carried out together in co-dependent relationship.

Hereinafter, the example embodiments of the present disclosure will be described in detail with reference to the accompanying drawings. All components of each display apparatus according to all embodiments of the present disclosure are operatively coupled and configured.

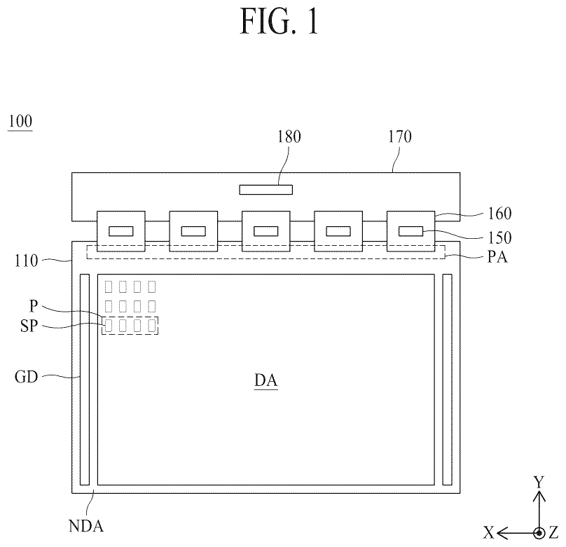

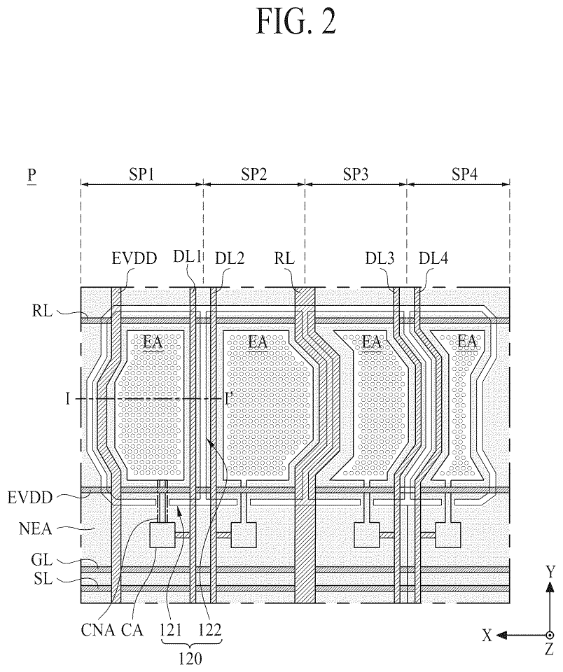

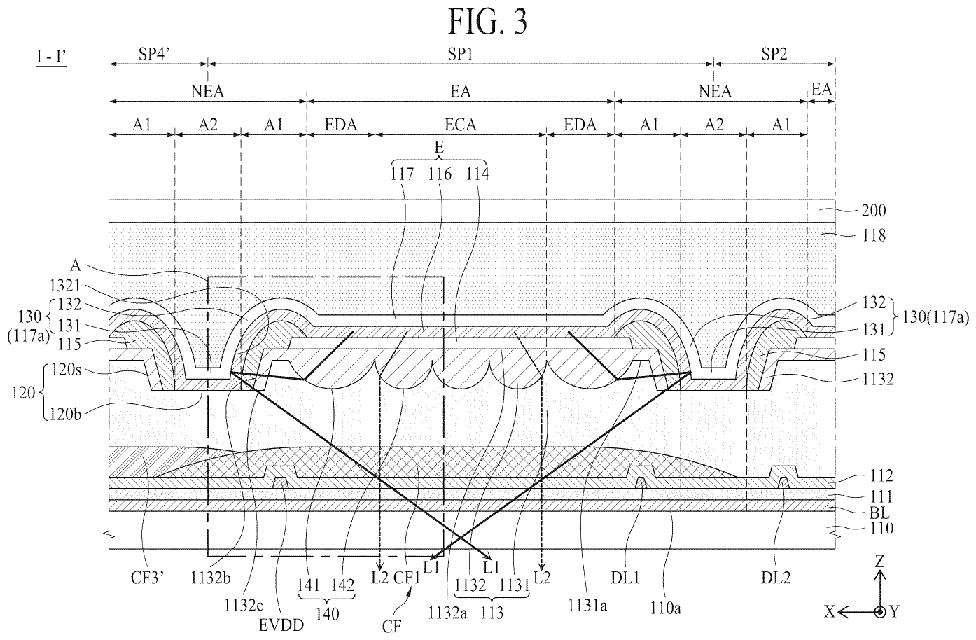

FIG. 1 is a schematic top view of a display apparatus according to one embodiment of the present disclosure, FIG. 2 is a schematic plan view illustrating one pixel shown in FIG. 1, and FIG. 3 is a schematic cross-sectional view of lines I-I′ shown in FIG. 2.

Hereinafter, referring to FIG. 2, a first direction (e.g., X-axis direction) is a horizontal direction, indicating a direction in which a gate line GL is extended, a second direction (e.g., Y-axis direction) is a perpendicular direction, indicating a direction in which a data line (e.g., a first data line DL1) is extended, and a third direction (e.g., Z-axis direction) is a direction intersecting each of the first direction (X-axis direction) and the second direction (Y-axis direction), indicating a thickness direction of the display apparatus 100.

Referring to FIGS. 1 to 3, a display apparatus 100 according to one embodiment of the present disclosure includes a substrate 110 having a plurality of pixels P having a plurality of subpixels SP, a pattern portion 120 disposed on the substrate 110 and formed to be concave between the plurality of subpixels SP, and a reflective portion 130 disposed to be inclined on the pattern portion 120.

The plurality of subpixels SP can include a plurality of the concave portions 140 spaced apart from the reflective portion 130 on the substrate 110. The plurality of the concave portions 140, according to one example, can include a first concave portion 141 disposed adjacent to the pattern portion 120, and a second concave portion 142 connected to the first concave portion 141 and disposed farther away from the pattern portion 120 than the first concave portion 141. For example, the second concave portion 142 can be disposed farther apart from the pattern portion 120 in the first direction (X-axis direction) than the first concave portion 141. The first concave portion 141 can have a different size from the second concave portion 142. For example, the first concave portion 141 can be provided with an aspect ratio that is smaller than an aspect ratio of the second concave portion 142. For example, the first concave portion 141 can be larger and wider than the second concave portion 142. Also, a depth of the first concave portion 141 can be the same or substantially the same as the depth of the second concave portion 142, but embodiments are not limited thereto. For example, a depth of the first concave portion 141 can be different than a depth of the second concave portion 142, according to another embodiment.

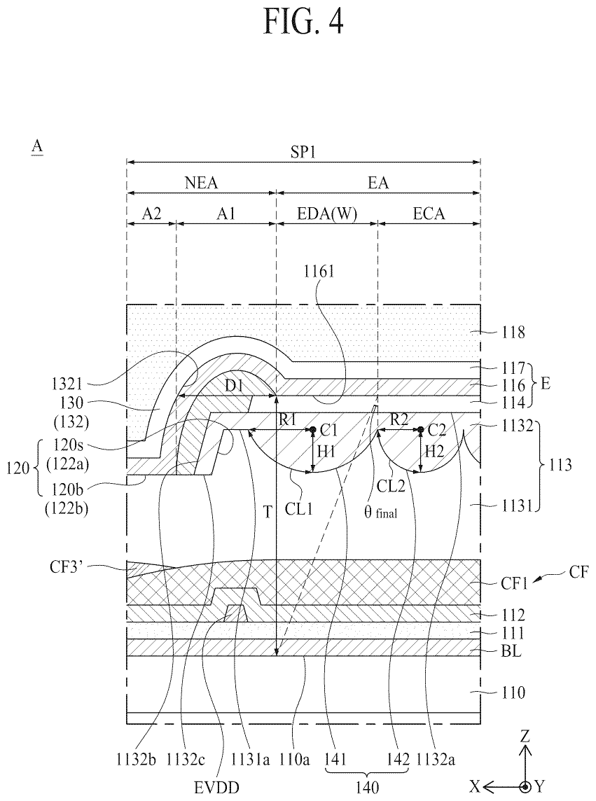

Referring to FIG. 4, the aspect ratio of the first concave portion 141 according to an example can be a ratio of a first perpendicular length H1 from a center C1 of the first concave portion to a boundary of the first concave portion 141 to a first radius R1 of the first concave portion 141. The boundary of the first concave portion 141 can refer to a surface where the interface between the first layer 1131 and the second layer 1132 of the overcoat layer 113 is lens shape with reference to FIG. 4 (e.g., the interface can be located at an upper surface or an uppermost surface of the first layer 1131). Also, the overcoat layer 113 can be referred to as an insulation layer. The first perpendicular length H1 can be a perpendicular length from the center C1 of the first concave portion 141 to the boundary of the first concave portion 141 and can be in a direction parallel to the third direction (Z-axis direction). The first radius R1 of the first concave portion 141 is a horizontal length from the center C1 of the first concave portion 141 to the boundary of the first concave portion 141, which can be in a direction parallel to the first direction (X-axis direction).

The aspect ratio of the second concave portion 142, according to one example, can be a ratio of a second perpendicular length H2 from a center C2 of the second concave portion 142 to a boundary of the second concave portion 142 to a second radius R2 of the second concave portion 142. The boundary of the second concave portion 142 is connected to the boundary of the first concave portion 141, which can refer to the lens shape interface between the first layer 1131 and the second layer 1132 of the overcoat layer 113 with reference to FIG. 4. The second perpendicular length H2 can be a perpendicular length from the center C2 of the second concave portion 142 to the boundary of the second concave portion 142, and can be in a direction parallel to the third direction (Z-axis direction). The second radius R2 of the second concave portion 142 is a horizontal length from the center C2 of the second concave portion 142 to the boundary of the second concave portion 142, which can be in a direction parallel to the first direction (X-axis direction).

The reason why the aspect ratio of the first concave portion 141 is smaller than the aspect ratio of the second concave portion 142 is to allow more light emitted from each of the plurality of subpixels SP to be incident on the first concave portion 141 to reach the reflective portion 130. In other words, if first concave portion 141 at the edge of the emission area is wider than the second concave portion 142, then more light can reach the reflective portion 130 and be reflected out of the device, in order to improve brightness and light extraction efficiency. For example, if the aspect ratio of the first concave portion 141 is smaller than the aspect ratio of the second concave portion 142, the cross-sectional length CL1 (shown in FIG. 4) of the left boundary of the first concave portion 141 relative to the center C1 of the first concave portion 141 can be longer than the cross-sectional length CL2 (shown in FIG. 4) of the left boundary of the second concave portion 142 relative to the center C2 of the second concave portion 142. Thus, light incident on the first concave portion 141 can have a greater amount of the light refracted to the reflective portion 130 (or left reflective portion) via the left boundary of the first concave portion 141 having a longer length (or area) than the second concave portion 142.

Since FIG. 4 is an enlarged view of the left portion of the sub-pixel SP, the right portion of the sub-pixel SP can have a length of the right boundary of the first concave portion 141 relative to the center C1 of the first concave portion 141 longer than the length of the right boundary of the second concave portion 142 relative to the center C2 of the second concave portion 142. Thus, light incident on the first concave portion 141 can have a greater amount of the light refracted to the reflective portion 130 (or right reflective portion) via the right boundary of the first concave portion 141 having a longer length (or area) than the second concave portion 142. In other words, the larger first concave portions 141 can be disposed around the edge or the periphery of the pixel electrode 114 or an edge area EDA for allowing more light to be extracted out of the device, while the smaller second concave portions 142 can be positioned on the inside, e.g., surrounded by the first concave portions 141.

Accordingly, the display apparatus 100 according to one embodiment of the present disclosure can have the aspect ratio of the first concave portion 141 be smaller than the aspect ratio of the second concave portion 142, which can increase the amount of the light reaching the reflective portion 130 compared to when the first concave portion and the second concave portion are formed with the same aspect ratio (or the same size), thereby further improving the light extraction efficiency (or the light extraction efficiency of the reflected light L1) of the light directed to the outside of the substrate 110.

In addition, the display apparatus 100 according to one embodiment of the present disclosure can have the aspect ratio of the first concave portion 141 be smaller than the aspect ratio of the second concave portion 142, such that the amount of the light emitted laterally through the reflective portion 130 can be increased compared to when the first concave portion and the second concave portion are formed with the same aspect ratio (or the same size or to have the same width), thereby improving the viewing angle.

The display apparatus 100 according to one embodiment of the present disclosure can be provided such that the first radius R1 of the first concave portion 141 is larger than the second radius R2 of the second concave portion 142, and the first perpendicular length H1 of the first concave portion 141 is equal to the second perpendicular length H2 of the second concave portion 142. Thus, the aspect ratio of the first concave portion 141 can be smaller than the aspect ratio of the second concave portion 142.

On the other hand, in the display apparatus 100 according to one embodiment of the present disclosure, a width W of an edge area EDA in which at least a portion of the first concave portion 141 is disposed overlappingly can be determined by a mathematical formula. For example, the width W of the edge area EDA can be derived by a mathematical expression relating the perpendicular distance between the organic light emitting layer 116 and the substrate 110, and the largest angle at which light emitted by the organic light emitting layer 116 is directed to the outside of the substrate 110 without being totally reflected from the upper surface 110a of the substrate 110. This will be described later in connection with the mathematical expression and FIG. 4.

The display apparatus 100 according to one embodiment of the present disclosure can be provided such that at least a portion of the first concave portion 141 is disposed (or disposed to overlap) in the edge area EDA, such that the amount of the light refracted through the first concave portion 141 towards the reflective portion 130 can be increased, thereby maximizing light extraction efficiency. The edge area EDA, according to one example, is an area comprising an edge portion of a light emission area EA, which can be an area surrounding a center area ECA of the subpixel.

Hereinafter, reference to FIGS. 1 to 3, the display apparatus 100 according to an embodiment of the present specification will be described in more detail.

Each of the plurality of subpixels SP according to one example can include the light emission area EA, a non-light emission area NEA adjacent to the light emission area EA, and a plurality of concave portions 140 that at least partially overlap with the light emission area EA.

The light emission area EA is an area from which light is emitted, and can be included in the display area DA. As shown in FIG. 3, the light emission area EA can be spaced apart from the pattern portion 120. For example, the pattern portion 120 can have a shape or form that is similar to a trench, a depression or a moat that surrounds or mostly surrounds each of the subpixels. Since the reflective portion 130 is disposed on the pattern portion 120 (e.g., in the trench), the light emission area EA can be spaced apart from the reflective portion 130. For example, the light emission area EA can be spaced apart from the reflective portion 130 by a first distance D1 (e.g., as shown in FIG. 4). The first distance D1 can be the shortest horizontal distance between the light emission area EA and the reflective portion 130, and can be in a direction parallel to the first direction (X-axis direction). For example, first distance D1 can be a distance between a point where the organic light emitting layer 116 contacts an edge area of the pixel electrode 114 to a point on a lower surface of reflective portion 130 in an area overlapping the trench or the pattern portion 120 (e.g., see FIG. 4).

The non-light emission area NEA is an area from which light is not emitted or not produced, and can be an area adjacent to the light emission area EA. The non-light emission area NEA can be referred to as a peripheral area. The reflective portion 130 is spaced apart from the plurality of the concave portions 140 (or the light emission area EA) and can be disposed in the non-light emission area NEA (e.g., in areas between adjacent subpixels).

Therefore, in the display apparatus 100 according to one embodiment of the present disclosure, since the reflective portion 130 disposed in the non-light emission area NEA can reflect light, which is directed toward the subpixel adjacent thereto among light emitted from the light emission area EA, toward the subpixel SP for emitting light, light efficiency (or light extraction efficiency) of the subpixel SP for emitting light can be improved and color mixing between adjacent subpixels can be prevented.

On the other hand, the reflective portion 130 according to one example can be disposed inclinedly on the pattern portion 120 (e.g., on the depression or trench) in the non-light emission area NEA. Accordingly, light directed toward the reflective portion 130 among the light refracted by the plurality of the concave portions 140 can be reflected by the inclinedly disposed reflective portion 130 and directed to the outside of the substrate 110 (e.g., out of the display device and towards a user's eyes).

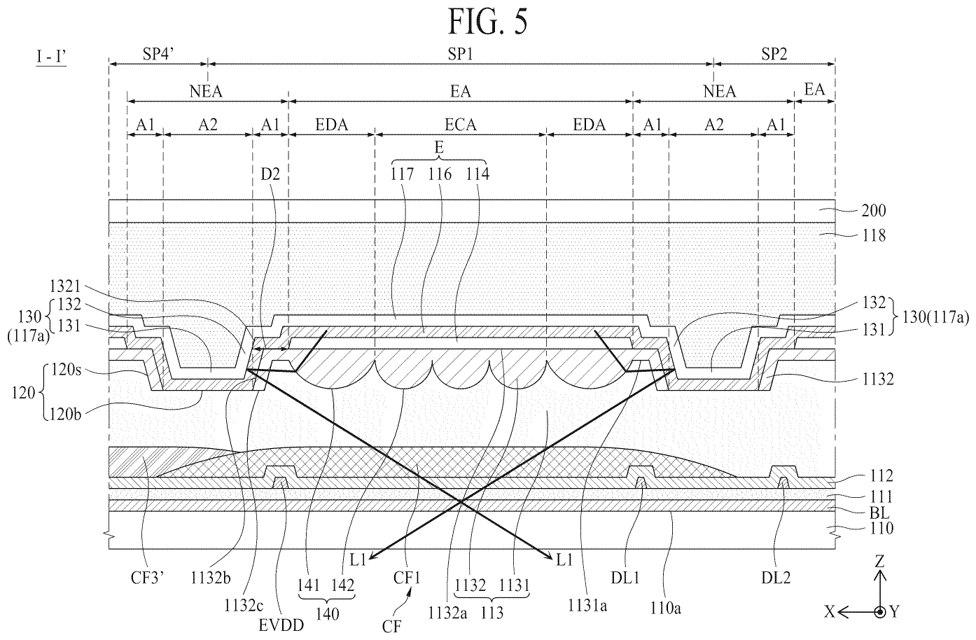

The non-light emission area NEA according to one example can include a first area A1 adjacent to the light emission area EA and a second area A2 adjacent to the first area A1 and spaced apart from the light emission area EA. The first area A1 according to one example can be a bank area in which a bank (or a bank 115 covering an edge of the pixel electrode 114) defining the light emission area EA is disposed. For example, the bank 115 can be disposed on opposite sides of the pattern portion 120 (e.g., on opposite sides of the trench/depression). In this way, the height of the reflective inclined portion of reflective portion 130 can be raised and the slope can be adjusted or made steeper to control more light to be reflected out of the device. The second area A2 according to one example can be a bank-less area in which a bank is not disposed in the non-light emission area NEA (e.g., the area between opposite sides of the trench or pattern portion 120). The first area A1, according to another example, can be an area adjacent to the light emission area EA and where the second layer 1132 of the overcoat layer 113 is partially disposed, as shown in FIG. 5. The second area A2, according to another example, can be adjacent to the first area A1 and can be an area where the organic light emitting layer 116 contacts the bottom surface 120b of the pattern portion 120, as shown in FIG. 5. For example, the second area A2 can correspond to the exposed lower surface of the trench or pattern portion 120 (e.g., the bottom that is exposed by the bank or exposed by the second layer 1132 of the overcoat layer 113, according to embodiments).

Referring back to FIG. 3, the pattern portion 120 according to one example can be formed to be concave in the non-light emission area NEA (e.g., to be a depression, a moat or trench configuration). For example, the pattern portion 120 can be formed to be concave in an overcoat layer 113 on the substrate 110. For example, the pattern portion 120 can be formed by etching or excavating material from the upper surface of the overcoat layer 113, but embodiments are not limited thereto. The pattern portion 120 can be a type of trench that surrounds a subpixel or partially surrounds a subpixel. The pattern portion 120 can be disposed to be spaced apart from the light emission area EA. The pattern portion 120 according to one example can be provided to surround the light emission area EA in the form of a slit or a trench. According to another embodiment, the pattern portion 120 can be a type of hole that extends all the way through the overcoat layer 113 to expose a layer there underneath. For example, a width of the pattern portion 120 can be formed to be reduced from the reflective portion 130 toward the substrate 110 (e.g., a cross section of the pattern portion 120 can have a reverse tapered shape relative to the substrate). Also, as shown in FIG. 3, the pattern portion 120 can include an exposed area of the overcoat layer 113 (e.g., an upper surface of the first layer 1131) that is not covered by the bank 115. Therefore, the pattern portion 120 can be expressed as terms such as a groove, a slit, a depression, a moat, a trench, a bank slit and a bank trench, but embodiments are not limited thereto. As shown in FIG. 3, the pattern portion 120 can include an inclined surface 120s formed in the first area A1 and a bottom surface 120b extending from the inclined surface 120s to the second area A2. The bottom surface 120b can be flat, but embodiments are not limited thereto. For example, according to another embodiment, the bottom surface 120b can be concaved.

The reflective portion 130 according to one example can be formed to be concave along a profile of the pattern portion 120 formed to be concave in the non-light emission area NEA, thereby being formed to be concave in the non-light emission area NEA (e.g., a cross section of the reflective portion 130 can form a type of “V” shape or “U” shape between adjacent subpixels). The reflective portion 130 can be made of a material capable of reflecting light, and can reflect light, which is emitted from the light emission area EA and directed toward the adjacent subpixel SP, toward the light emission area EA for emitting light. In other words, the reflective portion 130 can redirect light that is traveling towards an adjacent subpixel and change its path to be reflected out of the display device (e.g., color mixing can be prevented and light extraction efficiency can be improved). As shown in FIG. 3, since the reflective portion 130 is disposed to be inclined on the pattern portion 120 while surrounding the light emission area EA, the reflective portion 130 can be expressed as terms such as a side reflective portion or an inclined reflective portion or a reflective incline portion or a reflective slope portion.

In addition, the display apparatus 100 according to one embodiment of the present disclosure can be implemented as a bottom emission type in which light emitted from the light emission area EA is directed to the bottom surface of the substrate 110. Thus, as shown in FIG. 3, in the display apparatus 100 according to one embodiment of the present disclosure, light emitted from the lower surface of the substrate 110 can be a combination of a reflected light L1 and a direct light L2. In other words, the small second concave portions 142 overlapping the middle area of the subpixel can help align or create more direct light L2 that goes directly towards a user's eyes, while the larger first concave portions 141 can be located around the edge or periphery of the subpixel to help scavenge light escaping in a lateral type of direction and redirect it or convert it into reflected light L1 so that it can go towards the user's eyes. The reflected light L1 can mean light emitted from the light emitting area EA after a portion of the light emitted from the light emission area EA is refracted by at least one concave portion 140 and reflected by the reflective portion 130, and then emitted to the bottom surface of the substrate 110. The direct light L2 can mean light that a part of the light emitted from the light emission area EA is refracted by at least one concave portion 140 and directly emitted to the bottom surface of the substrate 110. Accordingly, the display apparatus 100 according to one embodiment of the present disclosure can have improved light extraction efficiency compared to a display apparatus that is not provided with the reflective portion 130 disposed to be inclined and color mixing between adjacent subpixels can be prevented.

Referring to FIGS. 1 and 2, a display apparatus 100 according to one embodiment of the present disclosure can further include a display panel, a plurality of the concave portions 140, a source drive integrated circuit (Hereinafter referred to as “IC”) 150, a flexible film 160, a circuit board 170, and a timing control portion 180, herein the display panel includes a gate driver GD, and the plurality of the concave portions 140 overlaps at least a portion of the light emission area EA.

The display panel can include a substrate 110 and an opposite substrate 200 (shown in FIG. 3).

The substrate 110 can include a thin film transistor, and can be a transistor array substrate, a lower substrate, a base substrate, or a first substrate. The substrate 110 can be a transparent glass substrate or a transparent plastic substrate. The substrate 110 can include a display area DA and a non-display area NDA.

The display area DA is an area where an image is displayed, and can be a pixel array area, an active area, a pixel array unit, a display unit, or a screen. For example, the display area DA can be disposed at a central portion of the display panel. The display area DA can include a plurality of pixels P.

The opposite substrate 200 can encapsulate (or seal) the display area DA disposed on the substrate 110. For example, the opposite substrate 200 can be bonded to the substrate 110 via an adhesive member (or clear glue). The opposite substrate 200 can be an upper substrate, a second substrate, or an encapsulation substrate.

The gate driver GD supplies gate signals to the gate lines in accordance with the gate control signal input from the timing controller 190. The gate driver GD can be formed on one side of the light emission area EA or in the non-light emission area NEA outside both sides of the light emission area EA in a gate driver in panel (GIP) method, as shown in FIG. 1.

The non-display area NDA is an area on which an image is not displayed, and can be a peripheral area, a signal supply area, an inactive area or a bezel area. The non-display area NDA can be configured to be in the vicinity of the display area DA. That is, the non-display area NDA can be disposed to surround the display area DA.

A pad area PA can be disposed in the non-display area NDA. The pad area PA can supply a power source and/or a signal for outputting an image to the pixel P provided in the display area DA. Referring to FIG. 1, the pad area PA can be provided above the display area DA.

The source drive IC 150 receives digital video data and a source control signal from the timing controller 180. The source drive IC 150 converts the digital video data into analog data voltages in accordance with the source control signal and supplies the analog data voltages to the data lines. Accordingly, the data lines can supply data signals to each of the plurality of subpixels. When the source drive IC 150 is manufactured as a driving chip, the source drive IC 150 can be packaged in the flexible film 160 in a chip on film (COF) method or a chip on plastic (COP) method.

Pads, such as data pads, can be formed in the non-display area NDA of the display panel. Lines connecting the pads with the source drive IC 150 and lines connecting the pads with lines of the circuit board 170 can be formed in the flexible film 160. The flexible film 160 can be attached onto the pads by using an anisotropic conducting film, whereby the pads can be connected with the lines of the flexible film 160.

The circuit board 170 can be attached to the flexible films 160. A plurality of circuits implemented as driving chips can be packaged in the circuit board 170. For example, the timing controller 180 can be packaged in the circuit board 170. The circuit board 170 can be a printed circuit board or a flexible printed circuit board.

The timing controller 180 receives the digital video data and a timing signal from an external system board through a cable of the circuit board 170. The timing controller 180 generates a gate control signal for controlling an operation timing of the gate driver GD and a source control signal for controlling the source drive ICs 150 based on the timing signal. The timing controller 180 supplies the gate control signal to the gate driver GD, and supplies the source control signal to the source drive ICs 150.

Referring to FIG. 3, the substrate 110 according to an example can include the light emission area EA and the non-light emission area NEA.

The light emission area EA can refer to an area where light is emitted and is not obscured by the bank 115. In the light emission area EA, a light emitting element layer E including a pixel electrode 114, an organic light emitting layer 116, and a reflective electrode 117 can be disposed. When an electric field is formed between the pixel electrode 114 and the reflective electrode 117, the organic light emitting layer 116 in the light emission area EA can be emitted. On the other hand, the light emission area EA can have the same or similar shape as the shape of the pixel electrode 114. This is because light can be emitted from the organic light emitting layer 116 depending on the formation of the electric field of the pixel electrode 114 and the reflective electrode 117. Since the area in which light is emitted is the light emission area EA, the light emission area EA can be formed along the shape of the pixel electrode 114. The pattern portion 120 according to one example is provided to surround the light emission area EA, and consequently, the pattern portion 120 (e.g., trench or depression) can be formed along the shape of the pixel electrode 114. For example, the pattern portion 120 can be spaced apart from the pixel electrode 114 and can extend around an outer perimeter of the pixel electrode 114. The light emission area EA can include the edge area EDA and the center area ECA.

The edge area EDA, according to one example, can be an area disposed adjacent to the reflective portion 130 in the non-light emission area NEA. The center area ECA according to one example can be an area disposed farther away from the reflective portion 130 than the edge area EDA. As shown in FIG. 3, the center area ECA can be an area that includes the center of the light emission area EA. Also, the edge area EDA can be an area including the edges of the light emission area EA, and can be an area surrounding the center area ECA.

In the display apparatus 100 according to one embodiment of the present disclosure, at least a portion of the first concave portion 141 can be disposed overlapping with the edge area EDA. Although only one first concave portion 141 partially overlapping the edge area EDA is shown in FIG. 3, at least one (or more) of the first concave portions 141 can overlap with the edge area EDA depending on the aspect ratio of the first concave portion 141. The second concave portion 142, according to an example, can be disposed overlapping with the center area ECA. As shown in FIG. 3, at least one (or more) of the second concave portions 142 can be disposed overlapping the center area ECA. However, not limited thereto, only one second concave portion 142 can be disposed overlapping the center area ECA.

As described above, the first concave portion 141 can be provided to have a smaller aspect ratio than the second concave portion 142. Thus, the display apparatus 100 according to one embodiment of the present disclosure can have an increased amount of the light reaching the reflective portion 130 disposed inclinedly on the pattern portion 120, which can result in an improved viewing angle and/or light extraction efficiency compared to a situation where the first concave portion and the second concave portion are formed with the same aspect ratio (or the same size), and color mixing between adjacent subpixels can be better prevented. Also, the configuration of the reflective portion 130 and the pattern portion 120 can allow the display device to be thinner while also improving light extraction and preventing color mixing, since additional layers and elements such as an additional black matrix can be avoided, omitted or made smaller.

Referring back to FIG. 2, the light emission area EA according to an example can include gate lines, data lines, pixel driving power lines, and a plurality of pixels P. Each of the plurality of pixels P can include a plurality of subpixels SP that can be defined by the gate lines and the data lines.

Meanwhile, at least four subpixels, which are provided to emit different colors and disposed to be adjacent to one another, among the plurality of subpixels SP can constitute one pixel P (or unit pixel). One pixel P can include, but is not limited to, a red subpixel, a green subpixel, a blue subpixel and a white subpixel. One pixel P can include three subpixels SP provided to emit light of different colors and disposed to be adjacent to one another. For example, one pixel P can include a red subpixel, a green subpixel and a blue subpixel.

Each of the plurality of subpixels SP includes a thin film transistor and a light emitting element layer E connected to the thin film transistor. Each of the plurality of subpixels can include a light emitting layer (or an organic light emitting layer) interposed between the pixel electrode and the reflective electrode.

The light emitting layer respectively disposed in the plurality of subpixels SP can individually emit light of different colors or emit white light in common. Since the light emitting layer of each of the plurality of subpixels SP commonly emit white light, each of the red subpixel, the green subpixel and the blue subpixel can include a color filter CF (or wavelength conversion member CF) for converting white light into light of its respective different color. In this situation, the white subpixel may not include a color filter.

In the display apparatus 100 according to one embodiment of the present disclosure, an area provided with a red color filter can be a red subpixel or a first subpixel, an area provided with a green color filter can be a green subpixel or a second subpixel, an area provided with a blue color filter can be a blue subpixel or a third subpixel, and an area in which the color filter is not provided can be a white subpixel or a fourth subpixel.

Each of the subpixels SP supplies a predetermined current to the organic light emitting element in accordance with a data voltage of the data line when a gate signal is input from the gate line by using the thin film transistor. For this reason, the light emitting layer of each of the subpixels can emit light with a predetermined brightness in accordance with the predetermined current.

The plurality of subpixels SP according to an example can be disposed adjacent in a first direction (X-axis direction). The plurality of the subpixels SPs can include a first subpixel SP1, a second subpixel SP2, a third subpixel SP3, and a fourth subpixel (SP4) disposed adjacent (or sequentially) in the first direction (X-axis direction). For example, the first subpixel SP1 can be a red subpixel, the second subpixel SP2 can be a white subpixel, the third subpixel SP3 can be a blue subpixel and the fourth subpixel SP4 can be a green subpixel, but is not limited thereto. However, the arrangement order of the first subpixel SP1, the second subpixel SP2, the third subpixel SP3 and the fourth subpixel SP4 can be changed.

Each of the first to fourth subpixels SP1 to SP4 can include a light emission area EA and a circuit area. The light emission area EA can be disposed at one side (or an upper side) of a subpixel area, and the circuit area CA can be disposed at the other side (or a lower side) of the subpixel area. For example, as shown in FIG. 2, the circuit area CA can be disposed at the lower side of the light emission area EA based on the second direction (Y-axis direction). The light emission areas EA of the first to fourth subpixels SP1 to SP4 can have same sizes (or areas) as each other, or different sizes (or areas) as each other.

The first to fourth subpixels SP1 to SP4 can be disposed to be adjacent to one another along the first direction (X-axis direction). For example, two data lines extended along the second direction (Y-axis direction) can be disposed in parallel with each other between the first subpixel SP1 and the second subpixel SP2 and between the third subpixel SP3 and the fourth subpixel SP4. A pixel power line EVDD extended along the first direction (X-axis direction) can be disposed between the light emission area EA and the circuit area of each of the first to fourth subpixels SP1 to SP4. The gate line GL and a sensing line SL can be disposed below the circuit area CA. The pixel power line EVDD (shown in FIG. 2) extended along the second direction (Y-axis direction) can be disposed at one side of the first subpixel SP1 or the fourth subpixel SP4. A reference line RL extended along the second direction (Y-axis direction) can be disposed between the second subpixel SP2 and the third subpixel SP3. The reference line RL can be used as a sensing line for sensing a change of characteristics of a driving thin film transistor and/or a change of characteristics of the light emitting element layer, which is disposed in the circuit area CA, from the outside in a sensing driving mode of the pixel P. At least a portion of the reference line RL according to one example can overlap the pattern portion 120. As shown in FIG. 2, at least a portion of the reference lines RL according to an example can overlap with the pattern portion 120. The data lines can include a first data line DL1 for driving the first sub-pixel SP1, a second data line DL2 for driving the second sub-pixel SP2, a third data line DL3 for driving the third sub-pixel SP3, and a fourth data line DL4 for driving the fourth sub-pixel SP4.

In the display apparatus 100 according to one embodiment of the present disclosure, the data lines, for example, the first data line DL1 can be disposed not to overlap with the light emission area EA and the reflective portion 130 (or a reflective portion 117a), herein the reflective portion 130 is disposed on the pattern portion 120. For example, as shown in FIG. 3, the first data line DL1 can be disposed to overlap with the first area A1. Accordingly, the display apparatus 100 according to one embodiment of the present disclosure can be prevented from reducing light extraction efficiency because the first data line DL1 does not obscure (or interfere with) the light reflected by the reflective portion 130 (or the reflective portion 117a). The second data line DL2, the third data line DL3, and the fourth data line DL4 can be disposed in the first area A1 of the corresponding sub-pixel, such as the first data line DL1 such that the light emission area EA and the reflective portion 117a of the corresponding sub-pixel, respectively, are not overlapped in the third direction (Z-axis direction). Thus, in the display apparatus 100 according to one embodiment of the present disclosure, the data lines DL1, DL2, DL3, DL4 can have structural features that do not overlap with the pattern portion 120. In other words, the configuration of the reflective portion 130 and the pattern portion 120 can be mainly spaced apart from wiring lines (e.g., RL, DL, EVDD, etc.) in a plan view without overlapping so that the wiring lines do not block much light reflected by the configuration of the reflective portion 130 and the pattern portion 120 (e.g., see FIG. 2).

However, and not necessarily limited thereto, the first data line DL1 can partially overlap with an inclined surface 120s of the pattern portion 120 between the first sub-pixel SP1 and the second sub-pixel SP2, according to another example. The second data line DL2 can partially overlap the bottom surface 120b of the pattern portion 120 between the first sub-pixel SP1 and the second sub-pixel SP2. The pixel power line EVDD or the reference line RL can partially overlap with the bottom surface 120b and the inclined surface 120s of the pattern portion 120.

In the display apparatus 100 according to one embodiment of the present disclosure, each of the data lines DL1, DL2, DL3, DL4 can be extended in a second direction (Y-axis direction) intersecting the first direction (X-axis direction) between the plurality of the subpixels SP disposed in the first direction (X-axis direction). The pattern portion 120 according to one example can partially overlap with the data lines DL1, DL2, DL3, DL4 in the first direction (X-axis direction) and the second direction (Y-axis direction), as shown in FIG. 2. As shown in FIG. 2, the pattern portion 120 is disposed to surround most of the light emission area EA.

In the display apparatus 100 according to one embodiment of the present disclosure, each of the plurality of the subpixels SP can include the plurality of the concave portions 140. The plurality of the concave portions 140 can be formed on the overcoat layer 113 to partially overlap with the light emission area EA of the subpixel. By forming the plurality of the concave portions 140 on the overcoat layer 113 of the light emission area EA to have a curved (or uneven) shape, the plurality of the concave portions 140 changes the progression path of the light emitted from the light-emitting element layer E to increase light extraction efficiency. For example, the plurality of the concave portions 140 can be a non-planar portion, an irregular pattern portion, a microlens portion, or a light scattering pattern portion.

The plurality of the concave portions 140 can be formed to be concave into an interior of the overcoat layer 113. For example, the plurality of the concave portions 140 can be concave formed onto the upper surface 1131a of the first layer 1131 included in the overcoat layer 113. Thus, the first layer 1131 can include the plurality of the concave portions 140. The first layer 1131 can be disposed between the substrate 110 and the light emitting element layer E in a third direction (Z-axis direction). The concave portions 140 can include the first concave portion 141 disposed adjacent to the pattern portion 120 in the first direction (X-axis direction) and a second concave portion 142 connected to the first concave portion 141 and disposed farther away from the pattern portion 120 than the first concave portion 141.

A second layer 1132 of the overcoat layer 113 can be disposed between the first layer 1131 and a light emitting element layer E (or a pixel electrode 114 shown in FIG. 3). The second layer 1132 according to one example can be formed to be wider than the pixel electrode 114 in a first direction (X-axis direction). Accordingly, a portion of the second layer 1132 can overlap with the light emission area EA, and the remainder can contact a portion of the bottom surface 120b while covering the inclined surface 120s of the pattern portion 120. That is, as shown in FIG. 3, the second layer 1132 can be extended from the light emission area EA to the first area A1 and contact a portion of the bottom surface 120b of the pattern portion 120 while covering the inclined surface 120s of the pattern portion 120. Since the upper surface 1132a of the second layer 1132 can be provided to be flat, the pixel electrodes 114 disposed on the upper surface 1132a of the second layer 1132 can also be flat. An organic light emitting layer 116 can be disposed on the pixel electrode 114.

On the other hand, the refractive index of the second layer 1132 can be greater than the refractive index of the first layer 1131. Accordingly, as shown in FIG. 3, a portion of the light emitted from the organic light emitting layer 116 and directed toward the substrate 110 can be rerouted toward the reflective portion 130 by the difference in refractive indices of the second layer 1132 and the first layer 1131 forming the plurality of the concave portions 140. For example, as shown in FIG. 3, a portion of the light emitted from the organic light emitting layer 116 and directed toward the substrate 110 can be refracted by the first concave portion 141 disposed adjacent to the pattern portion 120 then a light path is formed toward the reflective portion 130 (e.g., the light can be more straightly aligned via the difference in refractive indices so that it better reaches a user's eyes, such as the dotted lines L2). Thus, the light whose path is formed to the reflective portion 130 by the first concave portion 141 can be reflected by the reflective portion 130 and directed toward the light emission area EA of the sub-pixel SP that emits light. Thus, the display apparatus 100 according to one embodiment of the present disclosure can improve the viewing angle by increasing the amount of the light refracted by the first concave portion 141 disposed at an edge of the plurality of the concave portions 140 to the reflective portion 130, thereby increasing the amount of the light reflected by the reflective portion 130 and directed to the outside of the substrate 110. Hereinafter, the light reflected by the reflective portion 130 and directed toward the substrate 110 is defined as the reflected light L1.

On the other hand, in FIG. 3, only the light reflected by the reflective portion 130 and directed to the light emission area EA of the emitting sub-pixel SP (or the first sub-pixel SP1) is shown as an example, but the light reflected by the reflective portion 130 can be directed from the non-light emission area NEA surrounding the emitting sub-pixel SP (or the first sub-pixel SP1). Thus, the display apparatus 100 according to one embodiment of the present disclosure can maximize light extraction efficiency because, due to the reflective portion 130 disposed in the non-light emission area NEA, light can be extracted as the reflected light L1 even in the non-light emission area NEA.

The display apparatus 100, according to one embodiment of the present disclosure, can further include light that is not reflected by the reflective portion 130 and is incident on the substrate 110 through the plurality of the concave portions 140. For example, as shown by the dashed lines in FIG. 3, the display apparatus 100 can further include the direct light L2 that is emitted from the organic light emitting layer 116, incident on the plurality of the concave portions 140, refracted at the boundary of each of the plurality of the concave portions 140 (or at the interface between the second layer 1132 and the first layer 1131), and then directly directed to the substrate 110 and out of the display device. Thus, the display apparatus 100 according to one embodiment of the present disclosure can be able to direct light L1 and direct light L2 in the form of the reflected light L1 and the direct light L2 to the outside of the substrate 110 through the plurality of the concave portions 140 and reflective portions 130, thereby improving the overall light extraction efficiency.

In the display apparatus 100 according to one embodiment of the present disclosure, since the pattern portion 120 is disposed to surround the light emission area EA, at least a portion of the reflective portion 130 on the pattern portion 120 can be disposed to surround the light emission area EA. Therefore, the reflective light can be emitted toward the substrate 110 from the position spaced apart from the light emission area EA while surrounding at least a portion of the light emission area EA. Therefore, in the display apparatus 100 according to one embodiment of the present disclosure, since light dissipated by waveguide (or optical waveguide) and/or light dissipated by the interface total reflection can be emitted from the non-light emission area NEA in the form of reflective light through the reflective portion 130 surrounding at least a portion of the light emission area EA, light extraction efficiency can be improved and the overall light emission efficiency can be increased.

Hereinafter, a structure of each of the plurality of subpixels SP will be described in detail.

Referring to FIG. 3, the display apparatus 100 according to one embodiment of the present disclosure can further include a buffer layer BL, a circuit element layer, a thin film transistor, a pixel electrode 114, a bank 115, an organic light emitting layer 116, a reflective electrode 117, an encapsulation layer 118 and a color filter CF.

In more detail, each of the subpixels SP according to one embodiment can include a circuit element layer provided on an upper surface of a buffer layer BL, including a gate insulating layer, an interlayer insulating layer 111 and a passivation layer 112, an overcoat layer 113 provided on the circuit element layer, a pixel electrode 114 provided on the overcoat layer 113, a bank 115 covering an edge of the pixel electrode 114, an organic light emitting layer 116 on the pixel electrode 114 and the bank 115, a reflective electrode 117 on the organic light emitting layer 116, and an encapsulation layer 118 on the reflective electrode 117.

The thin film transistor for driving the subpixel SP can be disposed on the circuit element layer. The circuit element layer can be expressed in terms of an inorganic film layer. The pixel electrode 114, the organic light emitting layer 116 and the reflective electrode 117 can be included in the light emitting element layer E.

The buffer layer BL can be formed between the substrate 110 and the gate insulating layer to protect the thin film transistor. The buffer layer BL can be disposed on the entire surface (or front surface) of the substrate 110. The pixel power line EVDD for pixel driving can be disposed between the buffer layer BL and the substrate 110. However, not limited thereto, the pixel power lines EVDD can be disposed between the substrate 110 and the buffer layer BL. The buffer layer BL can serve to block outgassing or diffusion of a material contained in the substrate 110 into a transistor layer during a high temperature process of a manufacturing process of the thin film transistor. Optionally, the buffer layer BL can be omitted in some situations.

The thin film transistor (or a drive transistor) according to an example can include an active layer, a gate electrode, a source electrode, and a drain electrode. The active layer can include a channel area, a drain area and a source area, which are formed in a thin film transistor area of a circuit area of the subpixel SP. The drain area and the source area can be spaced parallel to each other with the channel area interposed therebetween.

The active layer can be formed of a semiconductor material based on any one of amorphous silicon, polycrystalline silicon, oxide and organic material.

The gate insulating layer can be formed on the channel area of the active layer. As an example, the gate insulating layer can be formed in an island shape only on the channel area of the active layer, or can be formed on an entire front surface of the substrate 110 or the buffer layer BL, which includes the active layer.

The gate electrode can be formed on the gate insulating layer to overlap the channel area of the active layer.

The interlayer insulating layer 111 can be formed to partially overlap the gate electrode and the drain area and source area of the active layer. The interlayer insulating layer 111 can be formed over the entire light emission area where light is emitted in the circuit area and the subpixel SP.

The source electrode can be electrically connected to the source area of the active layer through a source contact hole provided in the interlayer insulating layer overlapped with the source area of the active layer. The drain electrode can be electrically connected to the drain area of the active layer through a drain contact hole provided in the interlayer insulating layer 111 overlapped with the drain area of the active layer.

The drain electrode and the source electrode can be made of the same metal material. For example, each of the drain electrode and the source electrode can be made of a single metal layer, a single layer of an alloy or a multi-layer of two or more layers, which is the same as or different from that of the gate electrode.

Meanwhile, in the display apparatus 100 according to one embodiment of the present disclosure, the substrate 110 can include a connecting area CNA to which a thin film transistor in the circuit area CA and a pixel electrode 114 are connected. The connecting area CNA according to one example is an area where the thin film transistor in the circuit area CA and the pixel electrode 114 are connected. As shown in FIG. 2, the connecting area CNA according to one example can be an area between the light emission area EA and the circuit area CA. Since the connecting area CNA is an area where the thin film transistor 112 and the pixel electrode 114 are connected, the pattern portion 120 may not be formed in the connecting area CNA. For example, the pattern portion 120 can have a small area of disconnection to allow a wiring connection to pass therethrough. This is because if the pattern portion 120 is formed in the connecting area CNA, the thickness of the pixel electrode 114 can be thinned due to a step difference of the pattern portion 120, which can cause the pixel electrode 114 to be short-circuited. Therefore, the display apparatus 100 according to one embodiment of the present disclosure can be provided that the pattern portion 120 is not formed in the connecting area CNA, thereby preventing the connection between the pixel electrode 114 and the thin film transistor 112 from being weakened.

In addition, the circuit area can further include first and second switching thin film transistors disposed together with the thin film transistor, and a capacitor. Since each of the first and second switching thin film transistors is provided on the circuit area of the subpixel SP to have the same structure as that of the thin film transistor, its description will be omitted. The capacitor can be provided in an overlap area between the gate electrode and the source electrode of the thin film transistor, which overlap each other with the interlayer insulating layer 111 interposed therebetween.

Additionally, in order to prevent a threshold voltage of the thin film transistor provided in a pixel area from being shifted by light, the display panel or the substrate 110 can further include a light shielding layer provided below the active layer of at least one of the thin film transistor, the first switching thin film transistor or the second switching thin film transistor. The light shielding layer can be disposed between the substrate 110 and the active layer to shield light incident on the active layer through the substrate 110, thereby minimizing a change in the threshold voltage of the transistor due to external light. Also, since the light shielding layer is provided between the substrate 110 and the active layer, the thin film transistor can be prevented from being seen by a user.

The passivation layer 112 can be provided on the substrate 110 to cover the pixel area. The passivation layer 112 covers a drain electrode, a source electrode and a gate electrode of the thin film transistor, and the buffer layer. Between the passivation layer 112 and the interlayer insulating layer 111 are data lines, for example, as shown in FIG. 3, a first data line DL1 and a second data line DL2 can be disposed. The first data line DL1, the second data line DL2, and the pixel power line EVDD can be disposed in the non-light emission area NEA so as not to obscure the light emission area EA. The passivation layer 112 can be formed throughout the circuit area CA and the light emission area EA. These passivation layers 112 can also be omitted. A color filter CF can be disposed on the passivation layer 112.

The overcoat layer 113 can be provided on the substrate 110 to cover the passivation layer 112 and the color filter CF. When the passivation layer 112 is omitted, the overcoat layer 113 can be provided on the substrate 110 to cover the circuit area. The overcoat layer 113 can be formed in the circuit area in which the thin film transistor is disposed and the light emission area EA. In addition, the overcoat layer 113 can be formed in the other non-display area NDA except a pad area PA of the non-display area NDA and the entire display area DA. For example, the overcoat layer 113 can include an extension portion (or an enlarged portion) extended or enlarged from the display area DA to the other non-display area NDA except the pad area PA. Therefore, the overcoat layer 113 can have a size relatively wider than that of the display area DA.

The overcoat layer 113 according to one example can be formed to have a relatively thick thickness, thereby providing a flat surface on the display area DA and the non-display area NDA. For example, the overcoat layer 113 can be made of an organic material such as photo acryl, benzocyclobutene, polyimide and fluorine resin.

The overcoat layer 113 formed in the display area DA (or the light emission area EA) can include a plurality of concave portions 140 (e.g., concave portions 140 can have dimple shapes or pocked shapes). Also, the concave portions 140 can be alternatingly arranged in a plan view (e.g., a honeycomb arrangement). The plurality of concave portions 140 are the elements for increasing light efficiency of the light emission area EA, and can be formed inside the overcoat layer 113. In detail, as shown in FIG. 3, the plurality of concave portions 140 can be formed in a concave shape on the first layer 1131 of the overcoat layer 113. The plurality of the concave portions 140 (or the first concave portion 141 and the second concave portion 142) can be connected to each other.

The second layer 1132 having a refractive index higher than that of the first layer 1131 can be formed on the first layer 1131 (e.g., R index of 1132>R index of 1131). A path of the light, which is directed toward the adjacent subpixel SP, among the light emitted from the light emitting element layer E can be changed toward the reflective portion 130 in accordance with a difference in the refractive index between the second layer 1132 and the first layer 1131. The second layer 1132 can be provided to cover the plurality of the concave portions 140 provided in the first layer 1131 so that the upper surface 1132a can be flat.

The pixel electrode 114 is formed on the upper surface 1132a of the second layer 1132 so that the pixel electrode 114 can be provided to be flat, and the organic light emitting layer 116 and the reflective electrode 117, which are formed on the pixel electrode 114, can be provided to be also flat. Since the pixel electrode 114, the organic light emitting layer 116, the reflective electrode 117, that is, the light emitting element layer E is provided to be flat in the light emission area EA, a thickness of each of the pixel electrode 114, the organic light emitting layer 116 and the reflective electrode 117 in the light emission area EA can be uniformly formed. Therefore, the organic light emitting layer 116 can be uniformly emitted without deviation in the light emission area EA.

The plurality of concave portions 140 can be formed on the first layer 1131 through a photo process using a mask having an opening portion and then a pattern (or etching) or ashing process after the first layer 1131 is coated to cover the passivation layer 112 and the color filter CF, but embodiments are not limited thereto. The plurality of concave portions 140 can be formed in an area overlapped with the color filter CF and/or an area that is not overlapped with the bank 115 of the non-light emission area NEA. However, not limited thereto, the first concave portion 141 of the plurality of the concave portions 140 can be formed to partially overlap with the bank 115.

On the other hand, in the display apparatus 100 according to one embodiment of the present disclosure, the aspect ratio of the first concave portion 141 is provided to be smaller than the aspect ratio of the second concave portion 142, so that the first radius R1 of the first concave portion 141 and the second radius R2 of the second concave portion 142 can be provided to be different. The first concave portion 141 and the second concave portion 142 can be formed to have different radiuses when the size of the opening of the mask is different. Thus, the display apparatus 100 according to one embodiment of the present disclosure can be formed with the first concave portion 141 and the second concave portion 142 having different radiuses (or aspect ratios) without adding a mask, so that the light extraction efficiency through the first concave portion 141 can be improved without increasing the manufacturing cost.

Referring back to FIG. 3, the color filter CF disposed in the light emission area EA can be provided between the substrate 110 and the overcoat layer 113. Therefore, the color filter CF can be disposed between the pixel power line EVDD, for example, the pixel power line EVDD and the reflective portion 130 or between the pixel driving line and the pattern portion 120. The color filter CF can include a red color filter (or a first color filter) CF1 for converting white light emitted from the organic light emitting layer 116 into red light, a blue color filter (or a second color filter) CF2 for converting white light into blue light, and a green color filter (or a third color filter) CF3 for converting white light into green light. The fourth subpixel, which is a white subpixel, may not include a color filter since the organic light emitting layer 116 emits white light.

The display apparatus 100 according to one embodiment of the present disclosure can be provided such that color filters having different colors partially overlap at boundary portions of the plurality of subpixels SP. For example, as shown in FIG. 3, the first color filter CF1 of the first sub-pixel SP1 can partially overlap the third color filter CF3′ of the fourth sub-pixel SP4′ between the first sub-pixel SP1 and the fourth sub-pixel SP4′ of another pixel adjacent to the first sub-pixel SP1 (e.g., forming a type of black matrix in areas between adjacent subpixels). Thus, the display apparatus 100 according to one embodiment of the present disclosure can prevent light emitted from each sub-pixel from being directed to an adjacent sub-pixel due to the color filter overlapping at the boundary portions of the subpixels, thereby preventing color mixing between the subpixels. Also, the overlapping areas of the color filters (e.g., black matrix portion) can overlap with a center of the configuration of the reflective portion 130 and the pattern portion 120, in order to better prevent color mixing between subpixels.

The pixel electrode 114 of the subpixel SP can be formed on the overcoat layer 113. The pixel electrode 114 can be connected to a drain electrode or a source electrode of the thin film transistor through a contact hole passing through the overcoat layer 113 and the passivation layer 112. The edge portion of the pixel electrode 114 can be covered by the bank 115.

Because the display apparatus 100 according to an embodiment of the present disclosure is configured as the bottom emission type, the pixel electrode 114 can be formed of a transparent conductive material (or TCO), such as indium tin oxide (ITO) or indium zinc oxide (IZO) capable of transmitting light, or a semi-transmissive conductive material such as magnesium (Mg), silver (Ag), or an alloy of Mg and Ag.

Meanwhile, the material constituting the pixel electrode 114 can include MoTi. The pixel electrode 114 can be a first electrode or an anode electrode.

The bank 115 is an area from which light is not emitted, and can be provided to surround each of the light emitting portions (or the concave portions 141) of each of the plurality of subpixels SP. That is, the bank 115 can partition (or define) the concave portions 141 of each of the light emitting portion or the subpixels SP. The light emitting portion can mean a portion where the pixel electrode 114 and the reflective electrode 117 are in contact with each of the upper surface and the lower surface of the organic light emitting layer 116 with the organic light emitting layer 116 interposed therebetween.

The bank 115 can be formed to cover the edge of each pixel electrode 114 of each of the subpixels SP and expose a portion of each of the pixel electrodes 114. That is, the bank 115 can partially cover the pixel electrode 114. Therefore, the bank 115 can prevent the pixel electrode 114 and the reflective electrode 117 from being in contact with each other at the end of each pixel electrode 114. The exposed portion of the pixel electrode 114, which is not covered by the bank 115, can be included in the light emitting portion (or the light emission area EA). As shown in FIG. 3, the light emitting portion can be formed on the plurality of concave portions 140, and thus the light emitting portion (or the light emission area EA) can partially overlap the concave portions 140 in a thickness direction (or the third direction (Z-axis direction)) of the substrate 110. Also, the configuration of the bank 115, the reflective portion 130 and the pattern portion 120 can help prevent current leakage between adjacent subpixels.

After the bank 115 is formed, the organic light emitting layer 116 can be formed to cover the pixel electrode 114 and the bank 115. Therefore, the bank 115 can be provided between the pixel electrode 114 and the organic light emitting layer 116. The bank 115 can be expressed as the term of a pixel defining layer. The bank 115 according to one example can include an organic material and/or an inorganic material. As shown in FIG. 3, the bank 115 can be formed to be concave or inclined along the profile of the pattern portion 120 (or the second layer 1132).

Referring again to FIG. 3, the organic light emitting layer 116 can be formed on the pixel electrode 114 and the bank 115. The organic light emitting layer 116 can be provided between the pixel electrode 114 and the reflective electrode 117. Thus, when a voltage is applied to each of the pixel electrode 114 and the reflective electrode 117, an electric field is formed between the pixel electrode 114 and the reflective electrode 117. Therefore, the organic light emitting layer 116 can emit light. The organic light emitting layer 116 can be formed of a plurality of subpixels SP and a common layer provided on the bank 115.

The organic light emitting layer 116 according to an embodiment can be provided to emit white light. The organic light emitting layer 116 can include a plurality of stacks which emit lights of different colors. For example, the organic light emitting layer 116 can include a first stack, a second stack, and a charge generating layer (CGL) provided between the first stack and the second stack. The light emitting layer can be provided to emit the white light, and thus, each of the plurality of subpixels SP can include a color filter CF suitable for a corresponding color.

The first stack can be provided on the pixel electrode 114 and can be implemented a structure where a hole injection layer (HIL), a hole transport layer (HTL), an emission layer (EML (B)), and an electron transport layer (ETL) are sequentially stacked.

The charge generating layer can supply an electric charge to the first stack and the second stack. The charge generating layer can include an N-type charge generating layer for supplying an electron to the first stack and a P-type charge generating layer for supplying a hole to the second stack. The N-type charge generating layer can include a metal material as a dopant.

The second stack can be provided on the first stack and can be implemented in a structure where a hole transport layer (HTL), a yellow-green (YG) emission layer (EML (YG)), and an electron injection layer (EIL) are sequentially stacked.

In the display apparatus 100 according to an embodiment of the present disclosure, because the organic light emitting layer 116 is provided as a common layer, the first stack, the charge generating layer, and the second stack can be arranged all over the plurality of subpixels SP. On the other hand, the organic light emitting layer 116 is not limited to a two-stack tandem structure, but can be provided as a three-stack or four-stack tandem structure depending on the light emitting structure.

The reflective electrode 117 can be formed on the organic light emitting layer 116. The reflective electrode 117 can be disposed in the light emission area EA and the non-light emission area NEA. The reflective electrode 117 according to one example can include a metal material. The reflective electrode 117 can reflect the light emitted from the organic light emitting layer 116 in the plurality of subpixels SP toward the lower surface of the substrate 110. Therefore, the display apparatus 100 according to one embodiment of the present disclosure can be implemented as a bottom emission type display apparatus.

The display apparatus 100 according to one embodiment of the present disclosure is a bottom emission type and has to reflect light emitted from the organic light emitting layer 116 toward the substrate 110, and thus the reflective electrode 117 can be made of a metal material having high reflectance. The reflective electrode 117 according to one example can be formed of a metal material having high reflectance such as a stacked structure (Ti/Al/Ti) of aluminum and titanium, a stacked structure (ITO/Al/ITO) of aluminum and ITO, an Ag alloy and a stacked structure (ITO/Ag alloy/ITO) of Ag alloy and ITO. The Ag alloy can be an alloy such as silver (Ag), palladium (Pd) and copper (Cu). The reflective electrode 117 can be expressed as terms such as a second electrode, a cathode electrode and a counter electrode.

Meanwhile, in the display apparatus 100 according to one embodiment of the present disclosure, the reflective portion 130 can be a portion of the reflective electrode 117, but embodiments are not limited there to. For example, according to another embodiment, reflective portion 130 can be separate layer and disconnected from the reflective electrode 117. Therefore, the reflective portion 130 can reflect light, which is directed toward the adjacent subpixel SP, toward the light emission area EA of the subpixel SP for emitting light. Since the reflective portion 130 is a portion of the reflection electrode 117, as shown in FIG. 3, the reflective portion 130 can be denoted by a reference numeral 117a. In the present disclosure, the reflective portion 130 can mean the reflective electrode 117 that overlaps with the pattern portion 120. In particular, the reflective portion 130 can mean the reflective electrode 117 that is inclined while being overlapped with the pattern portion 120. Therefore, as shown in FIG. 3, the reflective portion 130 can reflect light that is directed toward the adjacent subpixel SP, or light that is dissipated through total reflection between interfaces, toward the light emission area EA (or the non-light emission area NEA) of the subpixel SP for emitting light.

The encapsulation layer 118 is formed on the reflective electrode 117. The encapsulation layer 118 serves to prevent oxygen or moisture from being permeated into the organic light emitting layer 116 and the reflective electrode 117. To this end, the encapsulation layer 118 can include at least one inorganic film and at least one organic film. The encapsulation layer 118 can be disposed not only in the light emission area EA but also in the non-light emission area NEA. The encapsulation layer 118 can be disposed between the reflective electrode 117 and an opposing substrate 200.

Referring to FIG. 3, the pattern portion 120 can be formed to be concave in the first layer 1131 of the overcoat layer 113 (e.g., a depression or trench). As shown in FIG. 3, the pattern portion 120 can be disposed near the non-light emission area NEA. That is, the pattern portion 120 can be disposed to surround the light emission area EA while being adjacent to the plurality of concave portions 140. The pattern portion 120 can be formed together in the non-light emission area NEA when the plurality of concave portions 140 are formed in the light emission area EA (e.g., during a same etching process or a same mask process, etc.). The pattern portion 120 can include a bottom surface 120b and an inclined surface 120s.

The bottom surface 120b of the pattern portion 120 according to one embodiment is a surface formed to be closest to the substrate 110, or can be disposed to be closer to the substrate 110 (or the upper surface 110a of the substrate) than the pixel electrode 114 (or the lower surface of the pixel electrode 114) in the light emission area EA. For example, a lowermost portion of the pattern portion 120 can be closer to the substrate than a lowermost surface of the pixel electrode 114. Therefore, the bottom surface 120b of the pattern portion 120 can be provided to have a depth equal to or similar to that of each of the plurality of concave portions 140. However, when the depth of the pattern portion 120 is less than a depth of the concave portion 140, since an area of the reflective portion 130 is reduced, light extraction efficiency can be reduced. Therefore, in the display apparatus 100 according to one embodiment of the present disclosure, the depth of the pattern portion 120 can be provided to be equal to or deeper than that of the concave portion 140 (e.g., the pattern portion 120 can be deeper or closer to the substrate than the concave portions 140).

The inclined surface 120s of the pattern portion 120 can be disposed between the bottom surface 120b and the plurality of concave portions 140. Therefore, the inclined surface 120s of the pattern portion 120 can be provided to surround the light emission area EA or the plurality of concave portions 140. As shown in FIG. 3, the inclined surface 120s can be connected to the bottom surface 120b. The inclined surface 120s can form a predetermined angle with the bottom surface 120b. For example, the angle formed by the inclined surface 120s and the bottom surface 120b can be an obtuse angle. Therefore, a width of the pattern portion 120 can be gradually reduced toward a direction (or the third direction (Z-axis direction)) from the opposing substrate 200 (or the reflective portion 130) toward the substrate 110. As the obtuse angle is formed by the inclined surface 120s and the bottom surface 120b, the second layer 1132, the bank 115, the organic light emitting layer 116 and the reflective portion 130, which are formed in a subsequent process, can be formed to be concave along the profile of the pattern portion 120.

As shown in FIG. 3, the pattern portion 120 can be provided to surround the light emission area EA. As the pattern portion 120 is provided to surround the light emission area EA, at least a portion of the reflective portion 130 disposed to be inclined on the pattern portion 120 can be provided to surround the light emission area EA. Therefore, in the display apparatus 100 according to one embodiment of the present disclosure, since light can be extracted even from the non-light emission area NEA near the edge of the light emission area EA, overall light efficiency can be improved. Therefore, the display apparatus 100 according to one embodiment of the present disclosure can have the same light emission efficiency or more improved light emission efficiency even with low power as compared with a general display apparatus having no pattern portion 120 and reflective portion 130, whereby overall power consumption can be reduced.

In addition, the display apparatus 100 according to one embodiment of the present disclosure can allow the light emitting element layer E to emit light even with low power, thereby improving lifespan of the light emitting element layer E (or the organic light emitting layer 116).

Since the pattern portion 120 is disposed to surround the light emission area EA, the pattern portion 120 can be disposed between the subpixels SP for emitting light of different colors. Therefore, the reflective portion 130 disposed to be inclined on the pattern portion 120 can be disposed between the subpixels SP for emitting light of different colors, whereby the reflective portion 130 can prevent light of different colors from being emitted to other adjacent subpixels SP. Therefore, the display apparatus 100 according to the present disclosure can prevent color mixture (or color distortion) from occurring between the subpixels SP for emitting light of different colors, thereby improving color purity and enhancing image quality.

Referring to FIG. 2, the pattern portion 120 can include a first pattern line 121 disposed in the first direction (X-axis direction) between the circuit area CA and the light emission area EA and a second pattern line 122 disposed in the second direction (Y-axis direction) crossing the first direction (X-axis direction). Referring to FIG. 2, the first pattern line 121 can mean the pattern portion 120 disposed in a horizontal direction, and the second pattern line 122 can mean the pattern portion 120 disposed in a vertical direction.

The first pattern line 121 can include a bottom surface and an inclined surface. The second pattern line 122 can include a bottom surface 122b and an inclined surface 122s. The bottom surface and the inclined surface of the first pattern line 121 and the bottom surface 122b and the inclined surface 122s of the second pattern line 122, respectively, are the same as the bottom surface 120b and inclined surface 120s of the pattern portion 120, respectively, and therefore will not be described herein. The first pattern line 121 and the second pattern line 122 can be connected together in the non-light emission area NEA (or periphery area) to surround the light emission area EA. The first pattern line 121 can be disposed between subpixels SP that emit the same color. The second pattern line 122 can be disposed between subpixels SP emitting different colors.

Since the second pattern line 122 is disposed between the subpixels SP for emitting light of different colors, the reflective portion 130 on the second pattern line 122 can prevent light of different colors from being emitted to other adjacent subpixels SP. Therefore, the display apparatus 100 according to the present disclosure can prevent color mixture (or color distortion) between the subpixels SP for emitting light of different colors, thereby improving color purity.

Further, since the second pattern line 122 is extended in the second direction (Y-axis direction) between the subpixels SP emitting different colors, the second pattern line 122 may not overlap the data line (e.g., the first data line DL1) in the second direction (Y-axis direction). In contrast, the first pattern line 121 is extended in the first direction (X-axis direction), thus the first pattern line 121 can partially overlap with the data line (e.g., the first data line DL1) in the second direction (Y-axis direction).

The second layer 1132 of the overcoat layer 113 can be further extended from the light emission area EA to the non-light emission area NEA to partially cover the inclined surface 120s of the pattern portion 120. Therefore, as shown in FIG. 3, an end 1132c of the second layer 1132 can be in contact with the bottom surface 120b of the pattern portion 120. In this situation, the end 1132c of the second layer 1132 can be in contact with only a portion of the bottom surface 120b. When the second layer 1132 entirely covers the bottom surface 120b, the depth of the reflective portion 130 formed on the pattern portion 120 can be relatively lowered, thereby reducing reflective efficiency. Therefore, in the display apparatus 100 according to one embodiment of the present disclosure, the second layer 1132 is provided to be in contact with only a portion of the bottom surface 120b without entirely covering the bottom surface 120b of the pattern portion 120 and thus the reflective portion 130 formed in a subsequent process can be formed to be close to the bottom surface 120b, whereby reflective efficiency can be improved.

The bank 115 can be extended to cover the inclined surface 1132b of the second layer 1132 covering the inclined surface 120s of the pattern portion 120 while covering the edge of the pixel electrode 114. Therefore, the bank 115 can be in contact with a portion of the bottom surface 120b of the pattern portion 120, which is not covered by the second layer 1132. When the bank 115 entirely covers the bottom surface 120b, the depth of the reflective portion 130 formed on the pattern portion 120 is lowered, whereby reflective efficiency can be reduced. Therefore, as shown in FIG. 3, each of the second layer 1132 and the bank 115 on the bottom surface 120b of the pattern portion 120 can be discontinuously provided. That is, each of the second layer 1132 and the bank 115 can be disconnected on the bottom surface 120b of the pattern portion 120. As a result, in the display apparatus 100 according to one embodiment of the present disclosure, the bank 115 is provided to be in contact with only a portion of the bottom surface 120b without entirely covering the bottom surface 120b, so that the reflective portion 130 formed in a subsequent process can be formed to be close to the bottom surface 120b, whereby reflective efficiency can be improved.

Since the bank 115 is provided to be in contact with only a portion of the bottom surface 120b of the pattern portion 120, the bank 115 can be disconnected from the pattern portion 120 as shown in FIG. 3. As the bank 115 is disconnected from the pattern portion 120, the reflective portion 130 disposed on the second pattern line 122 can be disposed to be close to the bottom surface 120b of the pattern portion 120. Therefore, the reflective portion 130 can be formed as deep as possible in the pattern portion 120 as compared with the situation that the bank is not disconnected from the pattern portion 120, and thus reflective efficiency can be improved. As shown in FIG. 3, since the pattern portion 120 is disposed between the subpixels SP, the second layer 1132, the bank 115, the organic light emitting layer 116 and the reflective portion 130 can be provided to be symmetrical based on the center of the pattern portion 120 (or the center of the second area A2).

In the display apparatus 100 according to one embodiment of the present disclosure, a plurality of wiring, for example, the pixel power line EVDD, the data line, and the reference line RL can be disposed so as not to obscure the light emission area EA (or so as not to overlap the light emission area EA). This is because if the plurality of wires overlap or cover the light emission area EA, light reflected by the reflective portion 130 can be blocked by the plurality of wires and can be not able to be emitted toward the substrate 110. Therefore, the display apparatus 100 according to one embodiment of the present disclosure can maximize the light extraction efficiency by being disposed in the non-light emission area NEA such that the plurality of wires do not overlap the light emission area EA. Furthermore, by providing the display apparatus 100 according to one embodiment of the present disclosure so that the plurality of wiring does not overlap with the light emission area EA, the aperture ratio can be enlarged compared to the situation where the plurality of wiring overlaps with the light emission area EA, and thus the luminance can be improved. In FIG. 3, the structure of the first data line DL1 and the second data line DL2 in the first subpixel SP1 and the second subpixel SP2 is described as an example, but the same structure can be applied to the third subpixel SP3 and the fourth subpixel SP4.

Meanwhile, as the bank 115 is disconnected from the pattern portion 120, the organic light emitting layer 116 and the reflective portion 130 (or the reflective electrode 117) formed in a subsequent process can be formed along a profile of the bottom surface 120b of the pattern portion 120 and the bank 115.

The reflective portion 130 according to one example can be formed to be concave on the pattern portion 120 along the profile of the pattern portion 120 formed to be concave near the non-light emission area NEA, thereby being formed to be concave near the non-light emission area NEA. The reflective portion 130, according to one example, can include a flat surface 131 disposed at a center portion of the second area A2 and an inclined surface 132 connected to the flat surface 131, as shown in FIG. 3. The inclined surface 132 can include a bottom surface 1321 (or side surface 1321) that reflects light that is refracted by the concave portion 140 and incident. The flat surface 131 can be disposed parallel to the bottom surface 120b of the pattern portion 120. The inclined surface 132 can be inclined along a profile of the inclined surface 120s of the pattern portion 120. The light directed toward the adjacent sub-pixel SP among the light emitted from the emitting sub-pixel SP can be mostly reflected by the inclined surface 132 (or bottom surface 1321) of the reflective portion 130 and can be directed into the light emission area EA of the emitting sub-pixel SP or the non-light emission area NEA of the emitting sub-pixel SP.

In the display apparatus 100 according to one embodiment of the present disclosure, a width W of the edge area EDA in which at least a portion of the first concave portion 141 is disposed overlappingly can be determined by a mathematical formula. For example, the width W of the edge area EDA can be derived by a mathematical expression relating the perpendicular distance between the organic light emitting layer 116 to the substrate 110, and the largest angle at which light emitted by the organic light emitting layer 116 is directed to the outside of the substrate 110 without being totally reflected from the upper surface 110a of the substrate 110. This will be described with reference to FIG. 4.

FIG. 4 is an enlarged view of portion A of FIG. 3.

Referring to FIG. 4, the width W of the edge area EDA is given by the following mathematical expression (or Equation 1 below), and can be provided to satisfy as below.

$$W = T \cdot tan {θ}_{final} \qquad [ Equation 1 ]$$

Here, T can denote a perpendicular distance between the bottom surface 1161 of the organic light emitting layer 116 and the upper surface 110a of the substrate 110. The perpendicular distance can be a distance in a direction parallel to the third direction (Z-axis direction), as shown in FIG. 4. θ_{final} can denote the largest angle at which light emitted by the organic light emitting layer 116 is directed to the outside of the substrate 110 without being totally reflected from the upper surface 110a of the substrate 110. In other words, θ_{final} can be the largest angle at which light is directed to the outside of the substrate 110 without being trapped by the substrate 110.

As shown in FIG. 4, the first radius R1 of the first concave portion 141 is larger than the second radius R2 of the second concave portion 142, such that the first concave portion 141 can partially overlap with the edge area EDA. For example, as shown in FIG. 4, a left portion of the first concave portion 141 can overlap the first area A1, and the remainder except for the left portion of the first concave portion 141, can overlap the edge area EDA. In FIG. 4, the first concave portion 141 partially overlap with the edge area EDA, but is not limited thereto, and the entire first concave portion 141 can overlap with the edge area EDA. In the display apparatus 100 according to one embodiment of the present disclosure, the first concave portion 141, which has a smaller aspect ratio than the second concave portion 142, is disposed to overlap with the edge area EDA, thus more light emitted from the organic light emitting layer 116 and incident on the first concave portion 141 can reach the reflective portion 130 through the left boundary of the first concave portion 141, thereby improving light extraction efficiency and/or viewing angle.

In the situation of a general display apparatus in which each of the plurality of the concave portions are formed in the same shape, the cavity condition is weaker in the edge area (or edge portion) than in the center portion of the light emission area, resulting in a decrease in light efficiency. This is because the concave portions in the edge portion are formed in the same form as the concave portions in the center portion, so that less light is refracted toward the reflective portion.

On the other hand, according to Equation 1 above, when the first concave portion 141 overlaps the center area ECA, the light emitted by the organic light emitting layer 116 is incident on the first concave portion 141 at an angle greater than θ_{final}, so that it is totally reflected from the substrate 110 and is not able to be directed to the outside of the substrate 110.

Thus, the display apparatus 100 according to one embodiment of the present disclosure is disposed such that the first concave portion 141, which has a smaller aspect ratio than the second concave portion 142, overlaps with the edge area EDA to satisfy Equation 1, so that the amount of the light that refracts the light incident on the first concave portion 141 to the reflective portion 130 can be increased, and thus, a decrease in light efficiency can be prevented or rather, light efficiency can be improved even in the edge area EA of the light emission area EA and the display device can be brighter and provide enhanced image quality.

In the display apparatus 100 according to one embodiment of the present disclosure, the largest angle θ_{final} (or emission angle θ_{final}) is an angle at which light emitted by the organic light emitting layer 116 is directed to the outside of the substrate 110 without being totally reflected from the upper surface 110a of the substrate 110, the angle θ_{substrate} (or extinction angle θ_{substrate}) is an angle at which light emitted by the organic light emitting layer 116 is totally reflected from the upper surface 110a of the substrate 110 and is not directed to the outside of the substrate 110, and the largest angle θ_{final} (or emission angle θ_{final}) can be provided to be smaller than the angle θ_{substrate} (or extinction angle θ_{substrate}). As described above, when the emission angle θ_{final} is equal to or greater than the extinction angle θ_{substrate}, light emitted by the organic light emitting layer 116 is totally reflected from the substrate 110 and may not be directed to the outside. Accordingly, the display apparatus 100 according to one embodiment of the present disclosure can be provided with an emission angle θ_{final} smaller than the extinction angle θ_{substrate}, so that light extraction efficiency can be improved because the light totally reflected from the substrate 110 (or the upper surface 110a of the substrate 110) can be eliminated or reduced.

On the other hand, the angle θ_{substrate} (or extinction angle θ_{substrate}) at which light emitted by the organic light emitting layer 116 is totally reflected from the upper surface 110a of the substrate 110 and may not be directed to the outside of the substrate 110 is given by the following mathematical expression (or Equation 2), and can be provided to satisfy as below.

$${θ}_{substrate} = arcsin ( \frac{{n}_{oc} 2}{{n}_{Anode}} sin ( arcsin ( \frac{{n}_{oc} 1}{{n}_{oc} 2} ) ) ) \qquad [ Equation 2 ]$$

In Equation 2, n_{Anode} can denote a refractive index of the pixel electrode 114, n_{oc1} can denote a refractive index of the first layer 1131, and n_{oc2} can denote a refractive index of the second layer 1132.

The display apparatus 100 according to one embodiment of the present disclosure can be provided with the emission angle θ_{final} smaller than the extinction angle θ_{substrate} satisfying Equation 2, such that light totally reflected from the substrate 110 (or the upper surface 110a of the substrate 110) can be eliminated or reduced, thereby improving light extraction efficiency.

FIG. 5 is a schematic cross-sectional view illustrating an example variation of a display apparatus according to one embodiment of the present disclosure. For example, the configuration in FIG. 5 is similar to the configuration in FIG. 3, but the bank 115 is omitted.

Referring now to FIG. 5, a variant example of the display apparatus 100 according to one embodiment of the present disclosure is identical to the display apparatus according to FIG. 3 described above, except that it is a bankless structure without the bank 115. Accordingly, the same drawing symbols have been assigned to the same configuration, and only the different configuration will be described hereinafter.

In the situation of the display apparatus according to FIG. 3, the bank 115 is provided to cover an edge of the pixel electrode 114 while surrounding the entire light emission area EA. Thus, in the situation of the display apparatus according to FIG. 3, the light emission area EA and the reflective portion 130 are spaced apart by a first distance (D1, shown in FIG. 4), a portion of the light emitted from the light emission area EA can be reflected from the reflective portion 130, or a portion of the light emitted from the light emission area EA can be refracted by the plurality of the concave portions 140 (or the first concave portion 141) and then reflected by the reflective portion 130 and directed to the non-light emission area NEA and/or the light emission area EA.

In contrast, in the display apparatus according to FIG. 5, the bank 115 covering the edges of the pixel electrodes 114 may not be provided (e.g., bank 115 is omitted). Therefore, as shown in FIG. 5, the reflective portion 130 can be spaced apart from the light emission area EA by a second distance D2 that is shorter than the first distance D1. Since the display apparatus according to FIG. 5 is provided as the bankless structure without a bank, the reflective portion 130 can be positioned as close to the light emission area EA as the thickness of the bank (e.g., the reflective portion 130 can be provided closer to the edge of the light emission area EA). When the distance between the reflective portion 130 and the light emission area EA is shortened, the light that is extinguished or impaired by the layers (e.g., the organic light emitting layer 116 in the non-light emission area NEA or the second layer 1132) provided between the reflective portion 130 and the light emission area EA is reduced, and thus, the light efficiency can be even further improved. Thus, in the display apparatus according to FIG. 5, the reflective portion 130 is spaced apart from the light emission area EA by a second distance D2 that is shorter than the first distance D1, the light efficiency of the light reflected by the reflective portion 130 among the light emitted by the organic light emitting layer 116 can be further improved.

On the other hand, the display apparatus 100 according to FIG. 5 is provided as the bankless structure, so that it can have a structural feature in which the organic light emitting layer 116 contacts the second layer 1132 (or an inclined surface 1132b of the second layer 1132) in the first area A1 and contacts the first layer 1131 (or the bottom surface 120b of the pattern portion 120) in the second area A2, as shown in FIG. 5.

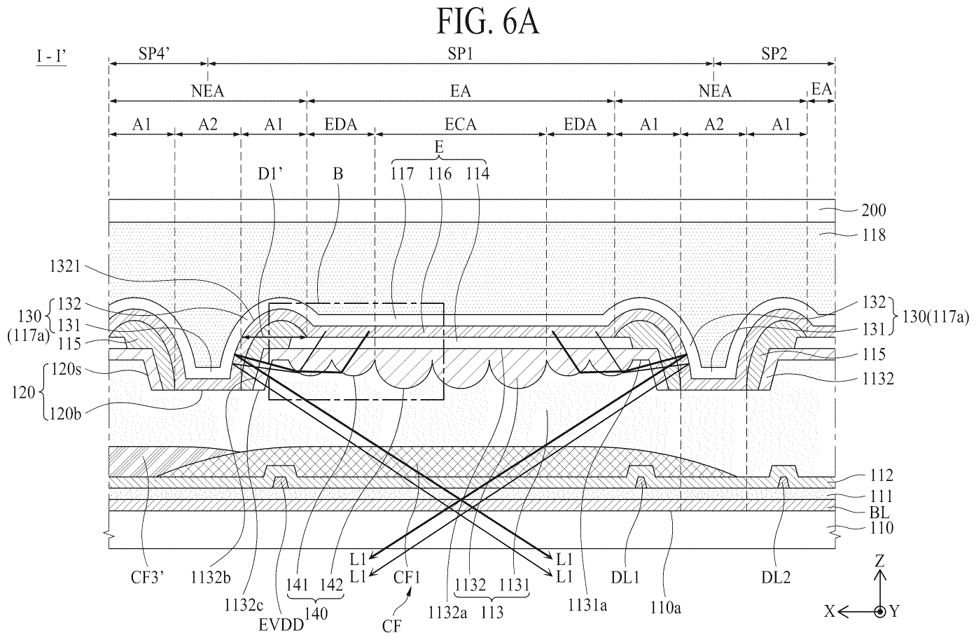

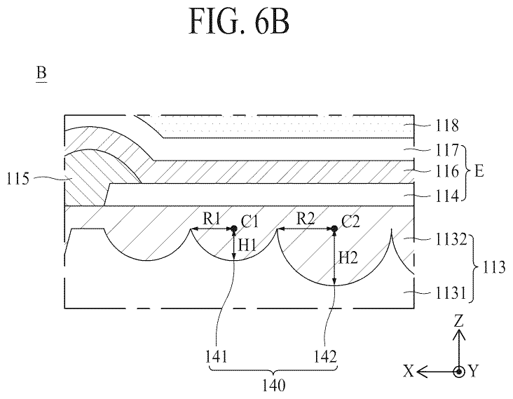

FIG. 6A is a schematic cross-sectional view of a display apparatus according to a second embodiment of the present disclosure, and FIG. 6B is an enlarged view of portion B of FIG. 6A.

Referring to FIGS. 6A and 6B, the display apparatus 100 according to a second embodiment of the present disclosure is identical to the display apparatus according to FIG. 3 described above, except that the structure of the first concave portion 141 disposed in the edge area EDA has been changed (e.g., the larger second concave portions 142 are located at the center of the subpixel, while the smaller first concave portions 141 are located around the edge of the subpixel). Therefore, the same drawing symbols have been assigned to the same configuration, and only the different configuration will be described hereinafter.

In the situation of the display apparatus according to FIG. 3 described above, it is provided that the first radius R1 of the first concave portion 141 is larger than the second radius R2 of the second concave portion 142, and the first perpendicular length H1 of the first concave portion 141 is equal to the second perpendicular length H2 of the second concave portion 142. Thus, in the situation of the display apparatus according to FIG. 3, one first concave portion 141 (or a portion of the first concave portion 141) can be disposed in the edge area EDA. Accordingly, the display apparatus according to FIG. 3 can be provided such that the cross-sectional length CL1 of the left boundary of the first concave portion 141 is longer than the cross-sectional length CL2 of the left boundary of the second concave portion 142, so that the amount of the light refracted to the reflective portion 130 can be increased, thereby improving light extraction efficiency.

In contrast, in the situation of the display apparatus according to FIG. 6A, the first radius R1 of the first concave portion 141 is smaller than the second radius R2 of the second concave portion 142, and the first perpendicular length H1 of the first concave portion 141 is smaller than the second perpendicular length H2 of the second concave portion 142. Thus, in the situation of the display apparatus according to FIG. 6A, at least one (or more) of the first concave portions 141 can be disposed in the edge area EDA. For example, as shown in FIG. 6A, the edge area EDA can fully overlap with one first concave portion 141, and can be partially overlap with another first concave portion 141. Accordingly, in the situation of the display apparatus according to FIG. 6A, light extraction efficiency can be improved because the amount of the light refracted to the reflective portion 130 can be increased due to the plurality of the first concave portions 141 overlapping the edge area EDA (e.g., a larger number of concave portions can be densely packed into the edge area EDA).

As a result, as shown in FIG. 6A, the display apparatus 100 according to a second embodiment of the present disclosure has at least one or more first concave portions 141 overlapping the edge area EDA and at least one or more second concave portions 142 overlapping the center area ECA, the amount of the light refracted to the reflective portion 130 via the plurality of the first concave portions 141 can be increased (e.g., since there is higher number of concave portions in the edge area EDA), thereby improving the light extraction efficiency of the reflected light, and the light extraction efficiency of the direct light via the second concave portions 142 can be improved. Since the reflected light is light that is reflected by the reflective portion 130 and directed to the outside of the substrate 110, improving the light extraction efficiency of the reflected light can mean improving the viewing angle. And, since improving the light extraction efficiency of the direct light can be referred that the amount of the light that is directed toward the front side rather than the side is increased, improving the front light extraction efficiency can mean including improving the front light extraction efficiency. Also, a depth of the first concave portions 141 can be less than a depth of the second concave portions 142.

On the other hand, in the situation of the display apparatus according to FIG. 3, only the radius of the first concave portion 141 and the second concave portion 142 are different from each other, but the perpendicular lengths are the same, so that the first concave portion 141 and the second concave portion 142 can be easily formed without an additional mask by varying only the size of the opening of one mask.

In contrast, in the situation of the display apparatus according to FIG. 6A, the first perpendicular length H1 of the first concave portion 141 is smaller than the second perpendicular length H2 of the second concave portion 142, so that the second concave portion 142 and the first concave portion 141 can be formed by different etching processes (or ashing processes). However, in the situation of the display apparatus according to FIG. 6A, the first perpendicular length H1 of the first concave portion 141 is provided to be smaller than the second perpendicular length H2 of the second concave portion 142, such that the refraction area of the light refracted by the first concave portion 141 and reaching the reflective portion 130 can be larger than the refraction area of the light refracted by the second concave portion 142 and reaching the reflective portion 130. In other words, the second concave portion 142 can be wider and deeper than the first concave portion 141. Thus, in the situation of the display apparatus according to FIG. 6A, the light path reaching the reflective portion 130 can be optimized due to the plurality of the first concave portions 141 disposed in the edge area EDA, which can increase the amount of the light reaching the reflective portion 130, thereby improving light extraction efficiency.

On the other hand, in the display apparatus 100 according to FIG. 6A, the bank 115 covers the edge of the pixel electrodes 114, so that the reflective portion 130 can be spaced apart from the light emission area EA by a first distance D1′.

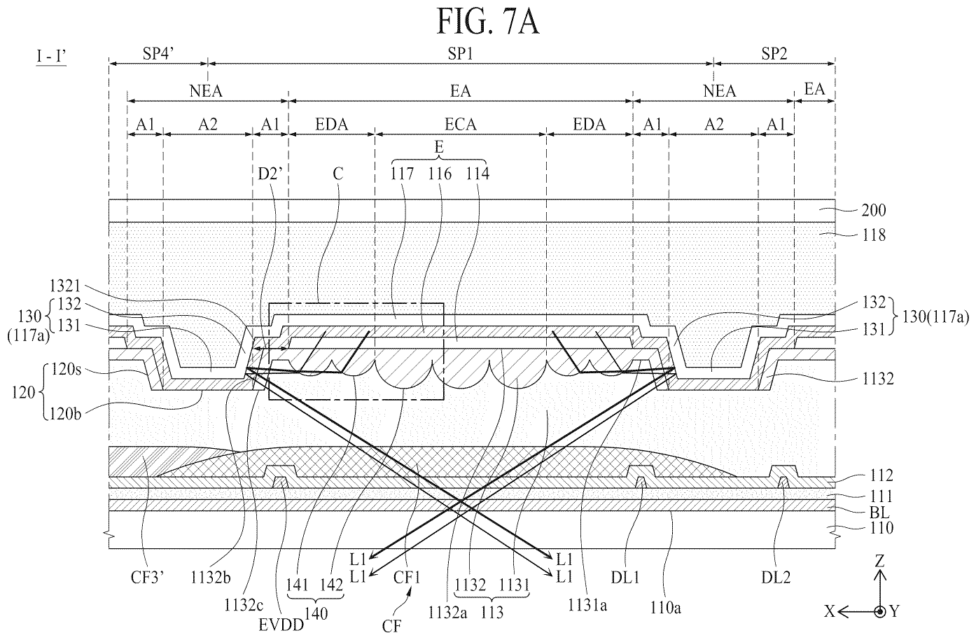

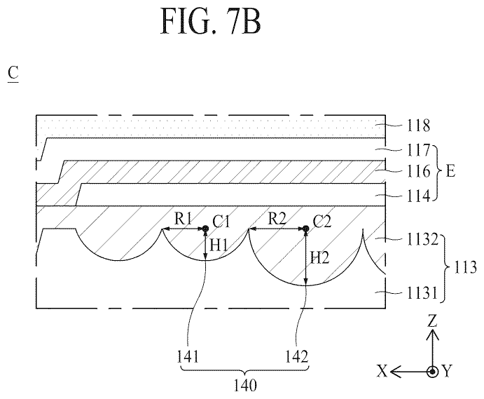

FIG. 7A is a schematic cross-sectional view illustrating a variant example of a display apparatus according to the second embodiment of the present disclosure and FIG. 7B is an enlarged view of portion C of FIG. 7A.

Referring to FIGS. 7A and 7B, a variant example of the display apparatus 100 according to a second embodiment of the present disclosure is identical to the display apparatus according to FIG. 6A described above, except that it is a bankless structure without the bank 115. Accordingly, the same drawing symbols have been assigned to the same configuration, and only the different configuration will be described hereinafter.

In the situation of the display apparatus according to FIG. 6A described above, the bank 115 is disposed to cover the edge of the pixel electrode 114 while surrounding the entire emission area EA. Thus, in the situation of the display apparatus according to FIG. 6A, the light emission area EA and the reflective portion 130 are spaced apart by a first distance (D1′, shown in FIG. 6A), a portion of the light emitted from the light emission area EA can be reflected from the reflective portion 130, or a portion of the light emitted from the light emission area EA can be refracted by the plurality of the concave portions 140 (or the first concave portion 141) and then reflected from the reflective portion 130 and directed to the non-light emission area NEA and/or the light emission area EA.

In contrast, in the display apparatus according to FIG. 7A, the bank 115 covering the edge of the pixel electrodes 114 may not be provided (e.g., the bank 115 can be omitted). Thus, as shown in FIG. 7A, the reflective portion 130 can be spaced apart from the light emission area EA by a second distance D2′ that is shorter than the first distance D1′. Since the display apparatus according to FIG. 7A is provided as a bankless structure without a bank, the reflective portion 130 can be positioned as close to the light emission area EA as the thickness of the bank. When the distance between the reflective portion 130 and the light emission area EA is shortened, the light that is extinguished or diffused by the layers (e.g., the organic light emitting layer 116 in the non-light emission area NEA or the second layer 1132) provided between the reflective portion 130 and the light emission area EA is reduced, and thus, the light efficiency can be further improved. Thus, in the display apparatus according to FIG. 7A, the reflective portion 130 is spaced apart from the light emission area EA by a second distance D2′ that is shorter than the first distance D1′, the light efficiency of the light reflected from the reflective portion 130 among the light emitted by the organic light emitting layer 116 can be even further improved.

On the other hand, the display apparatus 100 according to FIG. 7A is provided as a bankless structure, so that it can have a structural feature in which the organic light emitting layer 116 contacts the second layer 1132 (or the inclined surface 1132b of the second layer 1132) in the first area A1 and contacts the first layer 1131 (or the bottom surface 120b of the pattern portion 120) in the second area A2, as shown in FIG. 7A.

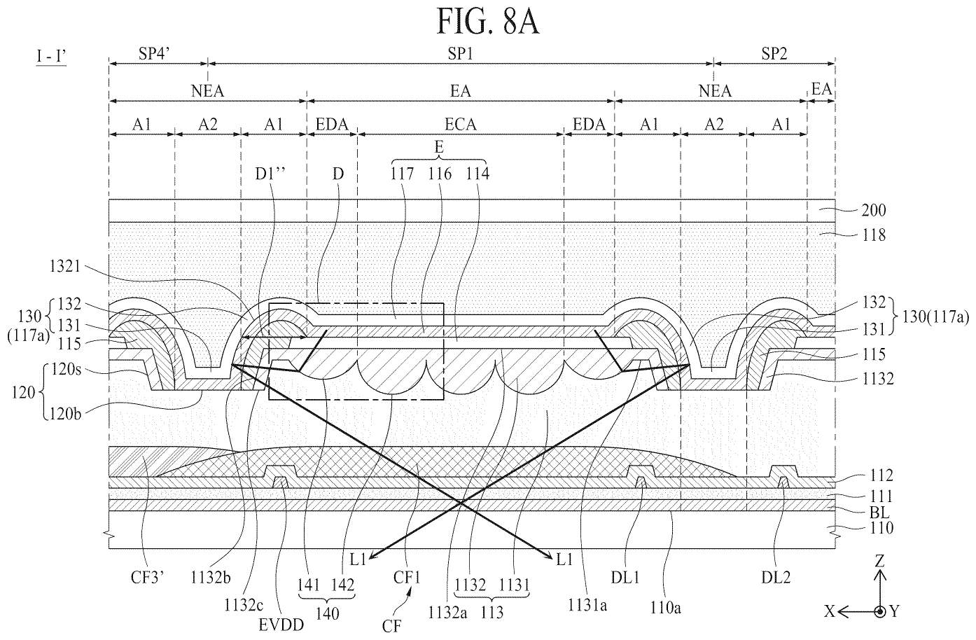

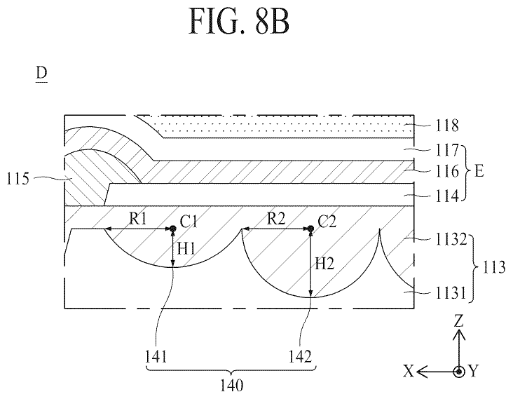

FIG. 8A is a schematic cross-sectional view of a display apparatus according to a third embodiment of the present disclosure, and FIG. 8B is an enlarged view of the D portion of FIG. 8A. Here, the first concave portion 141 and the second concave portion 142 can have a same width, but different depths.

Referring to FIGS. 8A and 8B, the display apparatus 100 according to the third embodiment of the present disclosure is the identical to the display apparatus according to FIG. 3 described above, except that the structure of the first concave portion 141 disposed in the edge area EDA has been changed. Therefore, the same drawing symbols have been assigned to the same configuration, and only the different configuration will be described hereinafter.

In the situation of the display apparatus according to FIG. 3 described above, it is provided that the first radius R1 of the first concave portion 141 is larger than the second radius R2 of the second concave portion 142, and the first perpendicular length H1 of the first concave portion 141 is equal to the second perpendicular length H2 of the second concave portion 142. Thus, in the situation of the display apparatus according to FIG. 3, one first concave portion 141 (or a portion of the first concave portion 141) can be disposed in the edge area EDA. Accordingly, the display apparatus according to FIG. 3 can be provided such that the cross-sectional length CL1 of the left boundary of the first concave portion 141 is longer than the cross-sectional length CL2 of the left boundary of the second concave portion 142, so that the amount of the light refracted to the reflective portion 130 can be increased, thereby improving light extraction efficiency.

In contrast, in the situation of the display apparatus according to FIG. 8A, the first radius R1 of the first concave portion 141 is equal to or substantially equal to the second radius R2 of the second concave portion 142, and the first perpendicular length H1 of the first concave portion 141 is smaller than the second perpendicular length H2 of the second concave portion 142. Thus, in the situation of the display apparatus according to FIG. 8A, one first concave portion 141 having a shallower depth than the second concave portion 142 can be disposed in the edge area EDA. For example, as shown in FIG. 8A, one first concave portion 141 having a shallower depth than the second concave portion 142 can partially overlap the edge area EDA. However, not limited thereto, one first concave portion 141 having a shallower depth than the second concave portion 142 can fully overlap with the edge area EDA. Accordingly, in the situation of the display apparatus according to FIG. 8A, light extraction efficiency can be improved because the amount of the light refracted to the reflective portion 130 can be increased due to the first concave portion 141 overlapping the edge area EDA.

Consequently, as shown in FIG. 8A, in the display apparatus 100 according to a third embodiment of the present disclosure, the first concave portion 141 having a depth shallower than the second concave portion 142 can partially overlap with the edge area EDA, such that the refractive area of the light refracted by the first concave portion 141 and reaching the reflective portion 130 can be increased, thereby increasing the amount of the light refracted to the reflective portion 130, thereby improving the light extraction efficiency (and/or the viewing angle) of the reflected light. Further, by disposing a plurality of the second concave portions 142 having the same radius as the first concave portion 141 in the center area ECA, the light extraction efficiency (and/or frontal light extraction efficiency) of direct light can be maximized.

On the other hand, in the situation of the display apparatus according to FIG. 8A, the first perpendicular length H1 of the first concave portion 141 is smaller than the second perpendicular length H2 of the second concave portion 142, so that the second concave portion 142 and the first concave portion 141 can be formed by different etching processes (or ashing processes). Furthermore, in the display apparatus 100 according to FIG. 8A, the bank 115 covers the edge of the pixel electrode 114, so that the reflective portion 130 can be spaced apart from the light emission area EA by a first distance D1″.

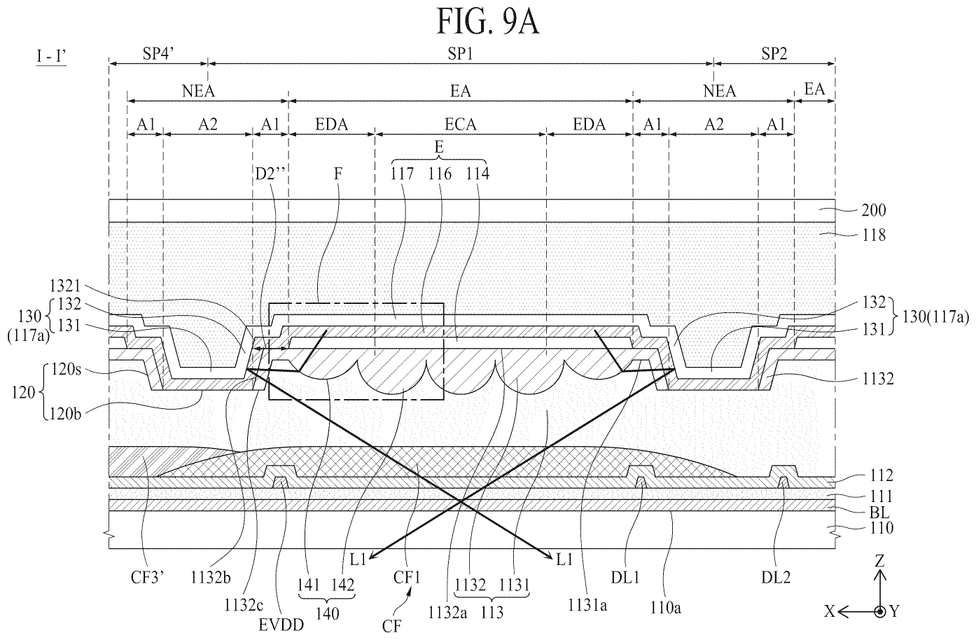

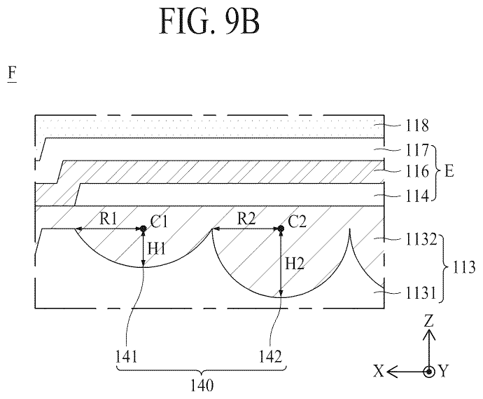

FIG. 9A is a schematic cross-sectional view illustrating a variant example of a display apparatus according to the third embodiment of the present disclosure, and FIG. 9B is an enlarged view of portion F of FIG. 9A. Here, the configuration in FIG. 9A is similar to the configuration of FIG. 8A, but the bank is removed to provide a bankless configuration.

Referring to FIGS. 9A and 9B, a variant example of the display apparatus 100 according to a third embodiment of the present disclosure is identical to the display apparatus according to FIG. 8A described above, except that it is a bankless structure without the bank 115. Accordingly, the same drawing symbols have been given to the same configuration, and only the different configuration will be described hereinafter.

In the situation of the display apparatus according to FIG. 8A, the bank 115 is provided to cover the edge of the pixel electrode 114 while surrounding the entire light emission area EA. Thus, in the situation of the display apparatus according to FIG. 8A, the light emission area EA and the reflective portion 130 are spaced apart by a first distance (D1″, shown in FIG. 8A), a portion of the light emitted from the light emission area EA can be reflected by the reflective portion 130, or a portion of the light emitted from the light emission area EA can be refracted by the plurality of the concave portions 140 (or the first concave portion 141) and then reflected by the reflective portion 130 and directed to the non-light emission area NEA and/or the light emission area EA.

In contrast, in the display apparatus according to FIG. 9A, the bank 115 covering the edges of the pixel electrodes 114 may not be provided. Thus, as shown in FIG. 9A, the reflective portion 130 can be spaced apart from the light emission area EA by a second distance D2″ that is shorter than the first distance D1″. Since the display apparatus according to FIG. 9A is provided as a bankless structure without a bank, the reflective portion 130 can be positioned as close to the light emission area EA as the thickness of the bank. When the distance between the reflective portion 130 and the light emission area EA is shortened, the light that is extinguished by the layers (e.g., the organic light emitting layer 116 in the non-light emission area NEA or the second layer 1132) provided between the reflective portion 130 and the light emission area EA is reduced, and thus, the light efficiency can be further improved. Thus, in the display apparatus according to FIG. 9A, the reflective portion 130 is spaced apart from the light emission area EA by a second distance D2″ that is shorter than the first distance D1″, so that the light efficiency of the light emitted by the organic light emitting layer 116 that is reflected by the reflective portion 130 can be even further improved.

On the other hand, the display apparatus 100 according to FIG. 9A is provided as a bankless structure, so that it can have a structural feature in which the organic light emitting layer 116 contacts the second layer 1132 (or the inclined surface 1132b of the second layer 1132) in the first area A1 and contacts the first layer 1131 (or the bottom surface 120b of the pattern portion 120) in the second area A2, as shown in FIG. 9A.

In the display panel of the present disclosure, the display panel can include a first subpixel and a second subpixel disposed on a substrate, the first subpixel being adjacent to the second subpixel, the first subpixel having a first light emission area and the second subpixel having a second light emission area, a pixel electrode disposed in the first subpixel, an insulation layer disposed between the pixel electrode and the substrate, the insulation layer including a plurality of concave portions including a first concave portion and a second concave portion having a different shape than the first concave portion, a pattern portion disposed between the first subpixel and the second subpixel, and a reflective portion overlapping with the pattern portion, thereby improving the extraction efficiency of light emitted from the light emitting layer.

Moreover, in the display apparatus of the present disclosure, the display apparatus can include a display panel including a plurality of subpixels, a gate driver configured to supply gate signals to gate lines connected to the plurality of subpixels, and a data driver configured to supply data signals to data lines connected to the plurality of subpixels, in which the display panel includes a first subpixel and a second subpixel disposed on a substrate, the first subpixel being adjacent to the second subpixel, the first subpixel having a first light emission area and the second subpixel having a second light emission area, a pixel electrode disposed in the first subpixel, an insulation layer disposed between the pixel electrode and the substrate, the insulation layer including a plurality of concave portions including a first concave portion and a second concave portion having a different shape than the first concave portion, a pattern portion disposed between the first subpixel and the second subpixel, and a reflective portion overlapping with the pattern portion. Thus, the amount of light reaching the reflective portion can be increased, thereby improving the viewing angle compared to a situation that the first concave portion and the second concave portion have the same size.

Moreover, in the display apparatus of the present disclosure, the reflective portion is configured to redirect light emitted from the first subpixel that has passed through one of the plurality of concave portions in a direction toward the substrate, thereby maximizing light extraction efficiency through light extraction in the non-light emission area.

Moreover, according to the display apparatus of the present disclosure, it can have the same luminous efficiency or even better luminous efficiency at lower power compared to a display apparatus without reflective portion, resulting in lower overall power consumption.

The effects to be obtained from the present disclosure are not limited to those mentioned above, and other effects not mentioned will be apparent to one of ordinary skill in the art from the description. Embodiments of the present disclosure have been described in more detail with reference to the accompanying drawings, but the present disclosure is not necessarily limited to these embodiments and can be practiced in various modifications without departing from the technical ideas of the present disclosure. Accordingly, the embodiments disclosed herein are intended to illustrate, not limit, the technical ideas of the present disclosure, and the scope of the technical ideas of the present disclosure is not limited by these embodiments. Therefore, the embodiments described above are examples in all respects and should be understood as non-limiting. All technical ideas within the scope of protection of this specification shall be construed to be included within the scope of the claims of this specification.

What is claimed is:

1. A display panel, comprising:
a first subpixel and a second subpixel disposed on a substrate, the first subpixel being adjacent to the second subpixel, the first subpixel having a first light emission area and the second subpixel having a second light emission area;
a pixel electrode disposed in the first subpixel;
an insulation layer disposed between the pixel electrode and the substrate, the insulation layer including a plurality of concave portions including a first concave portion and a second concave portion having a different shape than the first concave portion;
a pattern portion disposed between the first subpixel and the second subpixel; and
a reflective portion overlapping with the pattern portion.

2. The display panel of claim 1, wherein the reflective portion is configured to redirect light emitted from the first subpixel that has passed through one of the plurality of concave portions in a direction toward the substrate.

3. The display panel of claim 1, wherein the pattern portion is a trench formed in the insulation layer, and
wherein a lowermost surface of the trench is lower than the pixel electrode.

4. The display panel of claim 3, wherein the trench surrounds at least a majority of an outer perimeter of the pixel electrode in the first subpixel in a plan view, and
wherein the trench is spaced apart from the pixel electrode.

5. The display panel of claim 3, wherein a cross section of the trench has a “V” shape or a “U” shape in a non-emission area between the first subpixel and the second subpixel.

6. The display panel of claim 1, wherein the reflective portion is part of a reflective electrode of the first subpixel that extends continuously across the pattern portion.

7. The display panel of claim 1, wherein the first concave portion overlaps with an edge area of the pixel electrode and the second concave portion overlaps with a center area of the pixel electrode.

8. The display panel of claim 7, wherein the first concave portion at the edge area is wider than the second concave portion.

9. The display panel of claim 7, wherein the second concave portion is wider than the first concave portion at the edge area.

10. The display panel of claim 7, wherein a first depth of the first concave portion is different than a second depth of the second concave portion.

11. The display panel of claim 1, further comprising:
a bank disposed on an edge of the pixel electrode and overlapping with an inclined surface of the pattern portion.

12. The display panel of claim 1, further comprising:
a light emitting layer disposed in the first subpixel, the light emitting layer directly contacting an inclined surface of the pattern portion.

13. The display panel of claim 1, wherein the insulating layer includes a first layer having a first refractive index and a second layer having a second refractive index that is higher than the first refractive index, and
wherein the second layer is disposed between the pixel electrode and the first layer.

14. The display panel of claim 1, wherein the first concave portion is one of a plurality of first concave portions in the first subpixel, and the second concave portion is one of a plurality of second concave portions in the first subpixel, and
wherein a first aspect ratio of the plurality of first concave portions is different than a second aspect ratio of the plurality of second concave portions.

15. A display apparatus, comprising:
a display panel including a plurality of subpixels;
a gate driver configured to supply gate signals to gate lines connected to the plurality of subpixels; and
a data driver configured to supply data signals to data lines connected to the plurality of subpixels,
wherein the display panel includes:
a first subpixel and a second subpixel disposed on a substrate, the first subpixel being adjacent to the second subpixel, the first subpixel having a first light emission area and the second subpixel having a second light emission area,
a pixel electrode disposed in the first subpixel,
an insulation layer disposed between the pixel electrode and the substrate, the insulation layer including a plurality of concave portions including a first concave portion and a second concave portion having a different shape than the first concave portion,
a pattern portion disposed between the first subpixel and the second subpixel, and
a reflective portion overlapping with the pattern portion.

16. The display apparatus of claim 15, further comprising:
a first data line electrically connected to the first subpixel via a connecting portion of the pixel electrode,
wherein the pattern portion surrounds at least a majority of an outer perimeter of the pixel electrode of the first subpixel in a plan view,
wherein the pattern portion is spaced apart from the pixel electrode,
wherein the connecting portion of the pixel electrode passes between adjacent parts of the pattern portion without covering the pattern portion in the plan view, and
wherein a portion of the first data line crosses the pattern portion without covering the majority of the pattern portion in the plan view.

17. The display apparatus of claim 15, wherein the reflective portion is configured to redirect light emitted from the first subpixel that has passed through one of the plurality of concave portions in a direction toward the substrate.

18. The display apparatus of claim 15, wherein the pattern portion is a trench formed in the insulation layer, and
wherein a lowermost surface of the trench is lower than the pixel electrode.

19. The display apparatus of claim 18, wherein the trench surrounds at least a majority of an outer perimeter of the pixel electrode of the first subpixel in a plan view, and
wherein the trench is spaced apart from the pixel electrode.

20. The display apparatus of claim 18, wherein a cross section of the trench has a “V” shape or a “U” shape in a non-emission area between the first subpixel and the second subpixel.

21. The display apparatus of claim 15, wherein the reflective portion is part of a reflective electrode of the first subpixel that extends continuously across the pattern portion.

22. The display apparatus of claim 15, wherein the first concave portion overlaps with an edge area of the pixel electrode and the second concave portion overlaps with a center area of the pixel electrode.

23. The display apparatus of claim 22, wherein the first concave portion at the edge area is wider than the second concave portion.

24. The display apparatus of claim 22, wherein the second concave portion is wider than the first concave portion at the edge area.

25. The display apparatus of claim 22, wherein a first depth of the first concave portion is different than a second depth of the second concave portion.

26. The display apparatus of claim 15, further comprising:
a bank disposed on an edge of the pixel electrode and overlapping with an inclined surface of the pattern portion.

27. The display apparatus of claim 15, further comprising:
a light emitting layer disposed in the first subpixel, the light emitting layer directly contacting an inclined surface of the pattern portion.

28. The display apparatus of claim 15, wherein the insulating layer includes a first layer having a first refractive index and a second layer having a second refractive index that is higher than the first refractive index, and
wherein the second layer is disposed between the pixel electrode and the first layer.

29. The display apparatus of claim 15, wherein the first concave portion is one of a plurality of first concave portions in the first subpixel, and the second concave portion is one of a plurality of second concave portions in the first subpixel, and
wherein a first aspect ratio of the plurality of first concave portions is different than a second aspect ratio of the plurality of second concave portions.

30. The display apparatus of claim 15, further comprising:
a first data line electrically connected to the first subpixel,
wherein the first data line does not overlap with the pixel electrode.

31. A display apparatus, comprising:
the display panel of claim 1;
a gate driver configured to supply gate signals to gate lines connected to the first subpixel and the second subpixel; and
a data driver configured to supply data signals to data lines connected to the first subpixel and the second subpixel.

32. The display apparatus of claim 31, further comprising:
a power line connected to the first subpixel,
wherein the pattern portion surrounds at least a majority of an outer perimeter of the pixel electrode in the first subpixel in a plan view,
wherein the pattern portion is spaced apart from the pixel electrode,
wherein a portion of the power line crosses the pattern portion without covering a majority of the pattern portion in the plan view, and
wherein a portion of a first data line connected to the first subpixel crosses the pattern portion without covering the majority of the pattern portion in the plan view.
